(19) United States
(12) Patent Application Publication
(10) Pub. No.: US 2026/0117369 A1
(43) Pub. Date: Apr. 30, 2026

(54) DEPOSITION MASK AND METHOD OF MANUFACTURING THE SAME

(71) Applicant: Samsung Display Co., LTD., Yongin-si (KR)

(72) Inventors: Jun Ho JO, Yongin-si (KR); Jeong Kuk KIM, Yongin-si (KR); Duck Jung LEE, Yongin-si (KR); Yeon Woo LEE, Yongin-si (KR); Ji Hyun JUNG, Yongin-si (KR)

(73) Assignee: Samsung Display Co., LTD., Yongin-si (KR)

(21) Appl. No.: 19/234,506

(22) Filed: Jun. 11, 2025

(30) Foreign Application Priority Data
Oct. 24, 2024 (KR) 10-2024-0146256

(51) Int. Cl. C23C 16/04; H10K 59/12; H10K 71/16

(52) U.S. Cl. CPC C23C 16/042; H10K 71/166; H10K 59/12

(57) ABSTRACT

Provided is a deposition mask. The deposition mask include a mask substrate disposed to surround a mask opening and having a first surface; and a plurality of mask patterns disposed to overlap the mask opening and spaced apart from each other with a pixel opening between the plurality of mask patterns, wherein each of the plurality of the mask patterns includes an upper surface facing a side of a perpendicular direction of the mask substrate and a lower surface facing the upper surface, a width of an upper surface is greater than a width of the lower surface, a width of the upper surface is about 10 μm or less, and the first surface of the mask substrate and the upper surface of the mask pattern are disposed on a same line.

### CROSS-REFERENCE TO RELATED APPLICATION(S)

This application claims priority to and benefits of Korean Patent Application No. 10-2024-0146256 under 35 U.S.C. § 119, filed on Oct. 24, 2024 in the Korean Intellectual Property Office, the entire contents of which are incorporated herein by reference.

### BACKGROUND

### 1. Technical Field

The disclosure relates to a deposition mask and a method of manufacturing the deposition mask.

### 2. Description of the Related Art

With the advance of information-oriented society, more and more demands are disposed on display devices for displaying images in various ways. The display device may be a display device such as a liquid crystal display, a field emission display and a light emitting display. The light emitting display may include an organic light emitting display device including an organic light emitting diode as a light emitting element or an inorganic light emitting display device including an inorganic light emitting diode as a light emitting element.

Recently, there is an increasing need for a display device that provides high-resolution images, for example, images with a resolution of 3000 PPI (Pixels Per Inch) or more. To this end, an organic light emitting diode on silicon (OLEDoS), which is a high-resolution small organic light emitting display device, is used. The OLEDoS is an image display device in which an organic light emitting diode (OLED) is disposed on a semiconductor wafer substrate including complementary metal oxide semiconductor (CMOS).

Meanwhile, in order to manufacture a self-luminous display device such as an organic light emitting display device, a deposition method is mainly used as a technology for depositing an organic material for each pixel, in which a thin film mask is firmly attached to a substrate to deposit the organic material at a required position. When depositing the organic material in a large-area organic light emitting display device, a fine metal mask (FMM), which is a thin-film metal mask, is widely used. However, this metal mask is not suitable for high-resolution patterning.

In this regard, in order to manufacture a high-resolution precise thin film mask, a fine silicon mask (FSM) manufactured using a semiconductor substrate such as a wafer is attracting attention.

### SUMMARY

Aspects of the disclosure provide a deposition mask for manufacturing a high-resolution display device and a method of manufacturing the same.

Aspects of the disclosure also provide a deposition mask that improved efficiency of a deposition process and a method of manufacturing the same.

Aspects of the disclosure also provide a deposition mask solving a coating layer peeling defect and a method of manufacturing the same.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, a deposition mask may include: a mask substrate disposed to surround a mask opening and having a first surface; and a plurality of mask patterns disposed to overlap the mask opening and spaced apart from each other with a pixel opening between the plurality of mask patterns, wherein each mask pattern includes an upper surface facing a side of a perpendicular direction of the mask substrate and a lower surface facing the upper surface, a width of an upper surface is greater than a width of the lower surface, a width of the upper surface is about 10 μm or less, and the first surface of the mask substrate and the upper surface of the mask pattern are disposed on a same line.

In an embodiment, each mask pattern may further include a side surface facing the mask opening and connecting the upper surface and the lower surface, and a first inclined angle formed by the upper surface and the side surface and a second inclined angle formed by the lower surface and the side surface are different.

In an embodiment, the first inclined angle may be an acute angle, and the second inclined angle may be an obtuse angle.

In an embodiment, the first inclined angle may have a value of 50 degrees to about 88 degrees.

In an embodiment, the second inclined angle may have a value of about 92 degrees to about 130 degrees.

In an embodiment, each mask pattern may have a reverse-tapered shape or an inverted trapezoid shape, and a height of the mask pattern may be about 15 μm or less.

In an embodiment, the mask substrate may include a second surface facing the first surface; and a first side surface facing the mask opening and connected to the first surface.

In an embodiment, the mask substrate may further include a second side surface connected to the second surface, the first surface and the second surface are connected to each other by the first side surface and the second side surface, and an inclined angle formed by the first surface and the first side surface may be an obtuse angle.

In an embodiment, one of the plurality of the mask patterns may be in contact with and covers the first side surface of the mask substrate.

In an embodiment, the first side surface may connect the first surface and the second surface, an inclined angle formed by the first surface and the first side surface may be an acute angle, and one of the plurality of the mask patterns is spaced apart from the first side surface of the mask substrate with the pixel opening between the one of the plurality of mask patterns and the first side surface of the mask substrate.

In an embodiment, each mask pattern may include a first coating layer, and the first coating layer may include: an upper surface disposed on a side of the perpendicular direction of the mask substrate; a lower surface facing the upper surface; and a first side surface connecting the upper surface and the lower surface, wherein an inclined angle formed by the upper surface and the first side surface may be about 50 degrees to about 88 degrees.

In an embodiment, each of the plurality of the mask patterns may further include a second coating layer including a different material from the first coating layer, the second coating layer has a reverse-tapered shape, the first coating layer includes silicon oxide, and the second coating layer includes silicon nitride.

In an embodiment, the mask pattern may further include a metal coating layer, and the metal coating layer covers the first coating layer and the second coating layer.

According to an aspect of the disclosure, a method of manufacturing a deposition mask, the method may include: forming a protrusion and a trench portion on a mask substrate; forming a coating layer on the mask substrate in a portion overlapping the trench portion; and forming a mask opening, a pixel opening, and a mask pattern by removing a mask substrate, wherein, in cross-section, the protrusion has a normal-tapered shape or a trapezoid shape, and a height of the protrusion is about 15 μm or less.

In an embodiment, in the forming the protrusion and the trench portion on the mask substrate, the protrusion may include a first surface facing a side of a perpendicular direction of the mask substrate; a second surface facing the first surface; and a first side surface connecting the first surface and the second surface, and a first inclined angle formed by the second surface and the first side surface is about 50 degrees to about 88 degrees.

In an embodiment, in the forming of the protrusion and the trench portion on the mask substrate, the protrusion may be formed in plural, and the protrusions are spaced apart from each other with the trench portion between the protrusions.

In an embodiment, in the forming of the protrusion and the trench portion on the mask substrate, a width of the trench portion may be about 10 μm or less.

In an embodiment, the protrusion and the trench portion may be formed as a portion of the mask substrate may be removed by an etching process.

In an embodiment, in the forming of the mask opening, the pixel opening, and the mask pattern by removing the mask substrate, in cross-section, the mask pattern may have a reverse-tapered shape.

In an embodiment, a method of manufacturing a display panel, the method may include: placing a substrate on a deposition mask; and forming light emitting material layers on the substrate by providing a gaseous light emitting material through the deposition mask, wherein the deposition mask may include: a mask substrate disposed to surround a mask opening and having a first surface; and a plurality of mask patterns disposed to overlap the mask opening and spaced apart from each other with a pixel opening between the plurality of mask patterns, wherein the mask pattern includes an upper surface facing a side of a perpendicular direction of the mask substrate and a lower surface facing the upper surface, a width of the upper surface is greater than a width of the lower surface, a width of the upper surface is about 10 μm or less, and the first surface of the mask substrate and the upper surface of the mask pattern are disposed on a same line, and the gaseous light emitting material is provided to the substrate through the mask opening and the pixel opening.

In accordance with the deposition mask and the method of manufacturing the same according to an embodiment of the disclosure, it is possible to manufacture a high-resolution display device.

In accordance with the deposition mask and the method for manufacturing the same according to an embodiment of the disclosure, it is possible to improve efficiency of a deposition process.

In accordance with the deposition mask and the method for manufacturing the same according to an embodiment of the disclosure, it is possible to solve a coating layer peeling defect.

However, effects according to the embodiments of the disclosure are not limited to those exemplified above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is an exploded schematic perspective view showing a display device according to an embodiment;

FIG. 2 is a schematic block diagram illustrating a display device according to an embodiment;

FIG. 3 is a schematic diagram of an equivalent circuit of a first sub-pixel according to an embodiment;

FIG. 4 is a schematic plan view illustrating an example of a display panel according to an embodiment;

FIGS. 5 and 6 are schematic plan views showing an arrangement of multiple pixels in a display area of FIG. 4;

FIG. 7 is a schematic cross-sectional view illustrating an example of a display panel taken along line X1-X1′ of FIG. 5;

FIG. 8 is an exploded schematic perspective view illustrating a head mounted display according to an embodiment;

FIG. 9 is a schematic perspective view showing an augmented reality content providing device according to an embodiment;

FIG. 10 is a rear exploded schematic perspective view of the augmented reality content providing device of FIG. 9;

FIG. 11 is a front exploded schematic perspective view of the augmented reality content providing device of FIG. 10;

FIG. 12 is a schematic plan view showing a mother semiconductor substrate including a display cell according to an embodiment;

FIG. 13 is a schematic plan view showing a deposition mask including a mask cell according to an embodiment;

FIG. 14 is a schematic diagram for explaining a deposition device that manufactures a display panel by using a deposition mask according to an embodiment;

FIG. 15 is a schematic cross-sectional view taken along line X2-X2′ of FIG. 13;

FIG. 16 is a schematic cross-sectional view of an enlarged mask pattern in FIG. 15;

FIG. 17 is a schematic cross-sectional view of an enlarged mask pattern in FIG. 15 according to another embodiment;

FIG. 18 is a schematic cross-sectional view of an enlarged mask pattern in FIG. 15 according to still another embodiment;

FIG. 19 is a schematic cross-sectional view of an enlarged mask pattern in FIG. 15 according to still another embodiment;

FIG. 20 is a schematic cross-sectional view taken along line X2-X2′ of FIG. 13 according to another embodiment;

FIG. 21 is a schematic flowchart showing a method of manufacturing a deposition mask according to an embodiment;

FIGS. 22 and 23 are schematic cross-sectional views of step (S100) of FIG. 21;

FIG. 24 is a schematic cross-sectional view of an enlarged area T in FIG. 23;

FIG. 25 is a schematic perspective view of an enlarged mask substrate including a protrusion in FIG. 24;

FIG. 26 is a schematic cross-sectional view of step (S200) of FIG. 21; and

FIGS. 27 and 28 are schematic cross-sectional views of step (S300) of FIG. 21.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in an embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. The X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. For example, “about” may mean within one or more standard deviations, or within ±20%, ±10%, or ±5% of the stated value.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. The blocks, units, and/or modules of some embodiments may be physically combined into more complex blocks, units, and/or modules without departing from the scope of the inventive concepts.

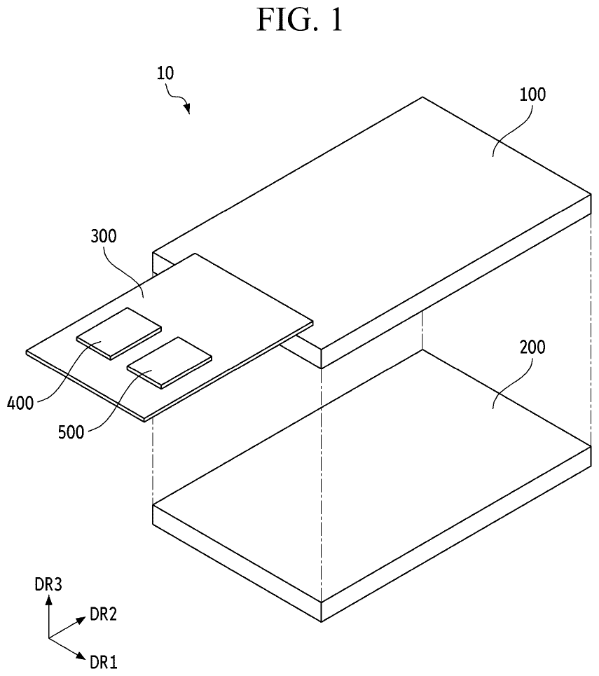

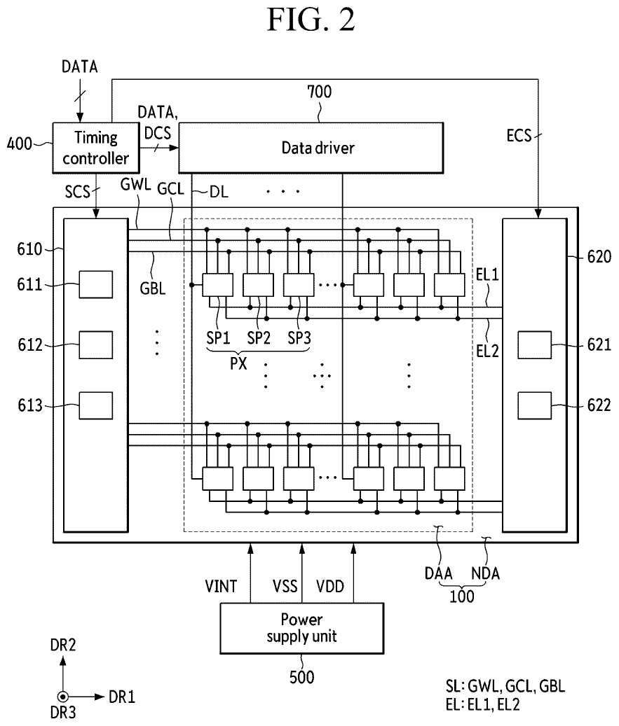

FIG. 1 is an exploded schematic perspective view showing a display device according to an embodiment. FIG. 2 is a schematic block diagram illustrating a display device according to an embodiment.

Referring to FIGS. 1 and 2, a display device 10 according to an embodiment may be a device displaying a moving image or a still image. The display device 10 according to an embodiment may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 according to an embodiment may be applied as a display unit of a television, a laptop, a monitor, a billboard, or an Internet-of-Things (IoT) terminal. In another embodiment, the display device 10 according to an embodiment may be applied to a smart watch, a watch phone, a head mounted display (HMD) for implementing virtual reality and augmented reality, and the like.

The display device 10 according to an embodiment may include a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the embodiment of the disclosure is not limited thereto.

In the illustrated figure, the first direction DR1 and the second direction DR2 cross each other as horizontal directions. For example, the first direction DR1 and the second direction DR2 may be orthogonal to each other. A third direction DR3 crosses the first direction DR1 and the second direction DR2, and they may be, for example, perpendicular directions orthogonal to each other. Unless otherwise defined, in the disclosure, directions indicated by arrows of the first to third directions DR1, DR2, and DR3 may be referred to as one side, and the opposite directions thereto may be referred to as the other side. Also, the terms “above,” “upper side,” “upper portion,” “top,” and “top surface,” as used herein, refer to a direction indicated by an arrow in the drawing in the third direction DR3 based on the drawings, and the terms “below,” “lower side,” “lower portion,” “bottom,” and “bottom surface,” as used herein, refer to a direction opposite to the direction indicated by the arrow in the third direction DR3 based on the drawings.

The display panel 100 may include a display area DAA displaying an image and a non-display area NDA not displaying an image as shown in FIG. 2.

The display area DAA may include multiple pixels PX, multiple scan lines SL, multiple emission control lines EL, and multiple data lines DL.

Multiple pixels PX may be arranged in a matrix form in the first direction DR1 and the second direction DR2. Multiple scan lines SL and multiple emission control lines EL may extend in the first direction DR1, while being disposed in the second direction DR2. Multiple data lines DL may extend in the second direction DR2, while being disposed in the first direction DR1.

Multiple scan lines SL may include multiple write scan lines GWL, multiple control scan lines GCL, and multiple bias scan lines GBL. Multiple emission control lines EL may include multiple first emission control lines EL1 and multiple second emission control lines EL2.

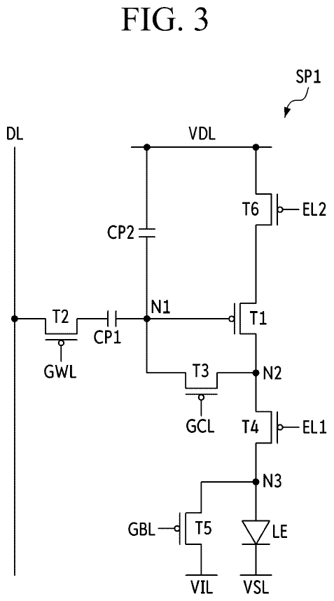

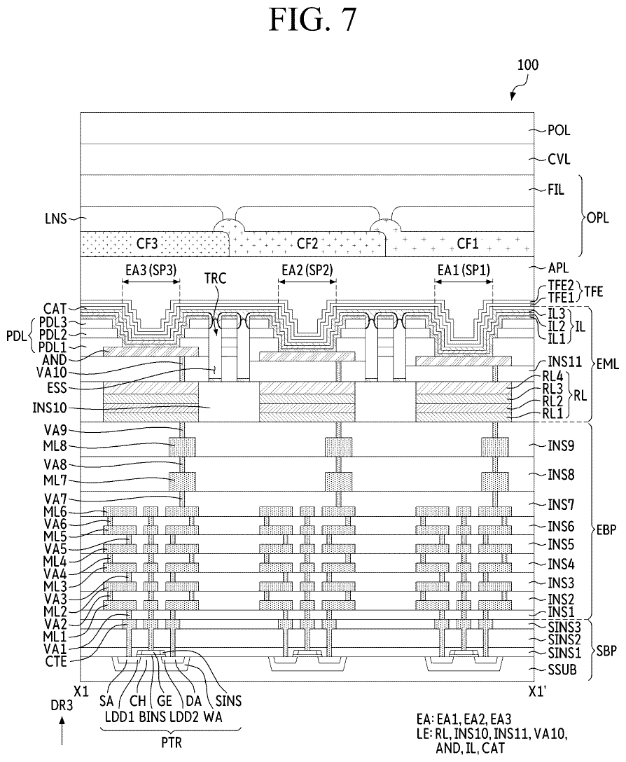

Multiple pixels PX may include multiple sub-pixels SP1, SP2, and SP3. The first to third sub-pixels SP1, SP2, and SP3 may include multiple pixel transistors as shown in FIG. 3 to be described later, and multiple pixel transistors may be formed by a semiconductor process and disposed on a semiconductor substrate SSUB (see FIG. 7). For example, multiple pixel transistors of a data driver 700 may be formed of complementary metal oxide semiconductor (CMOS).

Each of the first to third sub-pixels SP1, SP2, and SP3 may be electrically connected to a write scan line GWL among multiple write scan lines GWL, a control scan line GCL among multiple control scan lines GCL, a bias scan line GBL among multiple bias scan lines GBL, a first emission control line EL1 among multiple first emission control lines EL1, a second emission control line EL2 among multiple second emission control lines EL2, and a data line DL among multiple data lines DL. Each of the first to third sub-pixels SP1, SP2, and SP3 may receive a data voltage of the data line DL in response to a write scan signal of the write scan line GWL, and emit light from the light emitting element according to the data voltage.

The non-display area NDA may include a scan driver 610, an emission driver 620, and the data driver 700.

The scan driver 610 may include multiple scan transistors, and the emission driver 620 includes multiple light emitting transistors. Multiple scan transistors and multiple light emitting transistors may be formed through a semiconductor process, and disposed on the semiconductor substrate SSUB (see FIG. 7). For example, multiple scan transistors and multiple light emitting transistors may be formed of CMOS. Although it is illustrated in FIG. 2 that the scan driver 610 is disposed on the left side of the display area DAA and the emission driver 620 is disposed on the right side of the display area DAA, the disclosure is not limited thereto. For example, the scan driver 610 and the emission driver 620 may be disposed on both the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines EBL.

The emission driver 620 may include a first emission control driver 621 and a second emission control driver 622. Each of the first emission control driver 621 and the second emission control driver 622 may receive the emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include multiple data transistors, and multiple data transistors may be formed through a semiconductor process, and disposed on the semiconductor substrate SSUB (see FIG. 7). For example, multiple data transistors may be formed of CMOS.

The data driver 700 may receive digital video data DATA and a data timing control signal DCS from the timing control circuit 400. The data driver 700 may convert the digital video data DATA into analog data voltages according to the data timing control signal DCS and output the analog data voltages to the data lines DL. For example, the sub-pixels SP1, SP2, and SP3 are selected by the write scan signal of the scan driver 610, and data voltages may be supplied to the selected sub-pixels SP1, SP2, and SP3.

The heat dissipation layer 200 may overlap the display panel 100 in the third direction DR3, which is the thickness direction of the display panel 100. The heat dissipation layer 200 may be disposed on one surface of the display panel 100, for example, on the rear surface thereof. The heat dissipation layer 200 may serve to dissipate heat generated from the display panel 100. The heat dissipation layer 200 may include a metal layer having high thermal conductivity, such as graphite, silver (Ag), copper (Cu), or aluminum (Al).

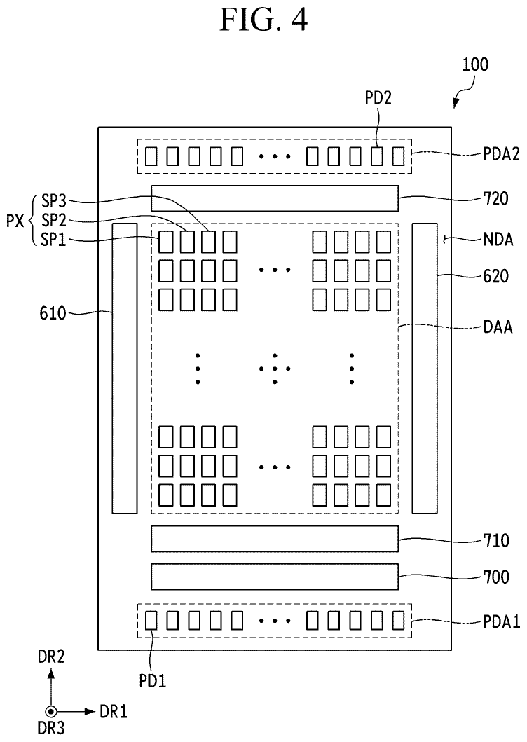

The circuit board 300 may be electrically connected to multiple first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. For example, an end of the circuit board 300 may be disposed on the rear surface of the display panel 100 and/or the rear surface of the heat dissipation layer 200. An end of the circuit board 300 may be an opposite end of another end of the circuit board 300 connected to multiple first pads PD1 (see FIG. 4) of the first pad portion PDA1 (see FIG. 4) of the display panel 100 by using a conductive adhesive member.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate multiple panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to one surface of the circuit board 300. For example, the scan timing control signal SCS, the emission timing control signal ECS, digital video data DATA, and the data timing control signal DCS of the timing control circuit 400 may be supplied to the display panel 100 through the circuit board 300. The first driving voltage VSS, the second driving voltage VDD, and the third driving voltage VINT of the power supply circuit 500 may be supplied to the display panel 100 through the circuit board 300.

In another embodiment, each of the timing control circuit 400 and the power supply circuit 500 may be disposed in the non-display area NDA of the display panel 100, similarly to the scan driver 610, the emission driver 620, and the data driver 700. For example, the timing control circuit 400 may include multiple timing transistors, and each power supply circuit 500 may include multiple power transistors. Multiple timing transistors and multiple power transistors may be formed through a semiconductor process, and disposed on the semiconductor substrate SSUB (see FIG. 7). For example, multiple timing transistors and multiple power transistors may be formed of CMOS. Each of the timing control circuit 400 and the power supply circuit 500 may be disposed between the data driver 700 and the first pad portion PDA1 (see FIG. 4).

FIG. 3 is a schematic diagram of an equivalent circuit of a first sub-pixel according to an embodiment.

Referring to FIG. 3 in addition to FIGS. 1 and 2, the first sub-pixel SP1 may be connected to the write scan line GWL, the control scan line GCL, the bias scan line GBL, the first emission control line EL1, the second emission control line EL2, and the data line DL. The first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. For example, the first driving voltage line VSL may be a low potential voltage line, the second driving voltage line VDL may be a high potential voltage line, and the third driving voltage line VIL may be an initialization voltage line. For example, the first driving voltage VSS may be lower than the third driving voltage VINT. The second driving voltage VDD may be higher than the third driving voltage VINT.

The first sub-pixel SP1 may include multiple transistors T1 to T6, a light emitting element LE, a first capacitor CP1, and a second capacitor CP2.

The light emitting element LE may emit light in response to a driving current (source-drain current) flowing through the channel of a first transistor T1. A light emission amount of the light emitting element LE may be proportional to the driving current. The light emitting element LE may be disposed between a fourth transistor T4 and the first driving voltage line VSL. The first electrode of the light emitting element LE may be connected to the drain electrode of the fourth transistor T4, and the second electrode thereof may be connected to the first driving voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but the embodiment of the disclosure is not limited thereto. For example, the light emitting element LE may be an inorganic light emitting element including a first electrode, a second electrode, and an inorganic semiconductor disposed between the first electrode and the second electrode, and the light emitting element LE may be, e.g., a micro light emitting diode.

The first transistor T1 may be a driving transistor that controls a driving current flowing between the source electrode and the drain electrode thereof according to a voltage applied to the gate electrode thereof. The first transistor T1 may include a gate electrode connected to a first node N1, a source electrode connected to the drain electrode of a sixth transistor T6, and a drain electrode connected to a second node N2.

A second transistor T2 may be disposed between an electrode of the first capacitor CP1 and the data line DL. The second transistor T2 may be turned on by the write scan signal of the write scan line GWL to connect the electrode of the first capacitor CP1 to the data line DL. Accordingly, the data voltage of the data line DL may be applied to the electrode of the first capacitor CP1. The second transistor T2 may include a gate electrode connected to the write scan line GWL, a source electrode connected to the data line DL, and a drain electrode connected to the electrode of the first capacitor CP1.

A third transistor T3 may be disposed between the first node N1 and the second node N2. The third transistor T3 may be turned on by the write control signal of the control scan line GCL to connect the first node N1 to the second node N2. For this reason, since the gate electrode and the source electrode of the first transistor T1 are connected, the first transistor T1 may operate like a diode. The third transistor T3 may include a gate electrode connected to the control scan line GCL, a source electrode connected to the second node N2, and a drain electrode connected to the first node N1.

The fourth transistor T4 may be connected between the second node N2 and a third node N3. The fourth transistor T4 may be turned on by the first emission control signal of the first emission control line EL1 to connect the second node N2 to the third node N3. Accordingly, the driving current of the first transistor T1 may be supplied to the light emitting element LE. The fourth transistor T4 may include a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 may be turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE. The fifth transistor T5 may include a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 may be turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be disposed between the first node N1 and the drain electrode of the second transistor T2. The first capacitor CP1 may include an electrode connected to the drain electrode of the second transistor T2 and another electrode connected to the first node N1.

The second capacitor CP2 may be disposed between the gate electrode of the first transistor T1 and the second driving voltage line VDL. The second capacitor CP2 may include an electrode connected to the gate electrode of the first transistor T1 and another electrode connected to the second driving voltage line VDL.

The first node N1 may be a junction disposed between the gate electrode of the first transistor T1, the drain electrode of the third transistor T3, another electrode of the first capacitor CP1, and the electrode of the second capacitor CP2. The second node N2 may be a junction disposed between the drain electrode of the first transistor T1, the source electrode of the third transistor T3, and the source electrode of the fourth transistor T4. The third node N3 may be a junction disposed between the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the embodiment of the disclosure is not limited thereto. Each of the first to sixth transistors T1 to T6 may be an N-type MOSFET. In another embodiment, some of the first to sixth transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors CP1 and CP2, the equivalent circuit diagram of the first sub-pixel SP1 is not limited to that shown in FIG. 3. For example, the number of the transistors and the number of the capacitors of the first sub-pixel SP1 may be changed in various ways.

The equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is omitted in the disclosure.

FIG. 4 is a schematic plan view illustrating an example of a display panel according to an embodiment.

Referring to FIG. 4 in addition to FIGS. 1 to 3, the display area DAA of the display panel 100 according to an embodiment may include multiple pixels PX arranged in a matrix form, and the non-display area NDA may include the scan driver 610, the emission driver 620, the data driver 700, a first distribution circuit 710, a second distribution circuit 720, the first pad portion PDA1, and a second pad portion PDA2. The description of overlapping content of the pixel PX, the scan driver 610, and the emission driver 620 is omitted.

The first pad portion PDA1 may include multiple first pads PD1 electrically connected to pads or bumps of the circuit board 300 through a conductive adhesive member. The first pad portion PDA1 may be disposed on a side of the display area DAA. For example, the first pad portion PDA1 may be disposed on the lower side of the display area DAA.

The first pad portion PDA1 may be disposed outside the data driver 700 in the second direction DR2. For example, the first pad portion PDA1 may be disposed closer to the edge of the display panel 100 than the data driver 700.

The second pad portion PDA2 may include multiple second pads PD2 corresponding to inspection pads that test whether the display panel 100 operates normally. The second pad portion PDA2 may be disposed another side of the display area DAA. For example, the second pad portion PDA2 may be disposed on the upper side of the display area DAA. Multiple second pads PD2 may be electrically connected to a jig or a probe pin during an inspection process, or may be electrically connected to a circuit board for inspection. The circuit board for inspection may be a printed circuit board made of a rigid material or a flexible printed circuit board made of a flexible material.

The first distribution circuit 710 may distribute data voltages applied through the first pad portion PDA1 to multiple data lines DL. For example, the first distribution circuit 710 may distribute the data voltages applied through one first pad PD1 of the first pad portion PDA1 to the P (P is a positive integer of 2 or more) data lines DL, and as a result, the number of multiple first pads PD1 may be reduced. The first distribution circuit 710 may be disposed on a side of the display area DAA of the display panel 100. For example, the first distribution circuit 710 may be disposed on the lower side of the display area DAA.

The second distribution circuit 720 may distribute signals applied through the second pad portion PDA2 to the scan driver 610, the emission driver 620, and the data lines DL. The second pad portion PDA2 and the second distribution circuit 720 may inspect the operation of each of the pixels PX in the display area DAA. The second distribution circuit 720 may be disposed on another side of the display area DAA of the display panel 100. For example, the second distribution circuit 720 may be disposed on the upper side of the display area DAA.

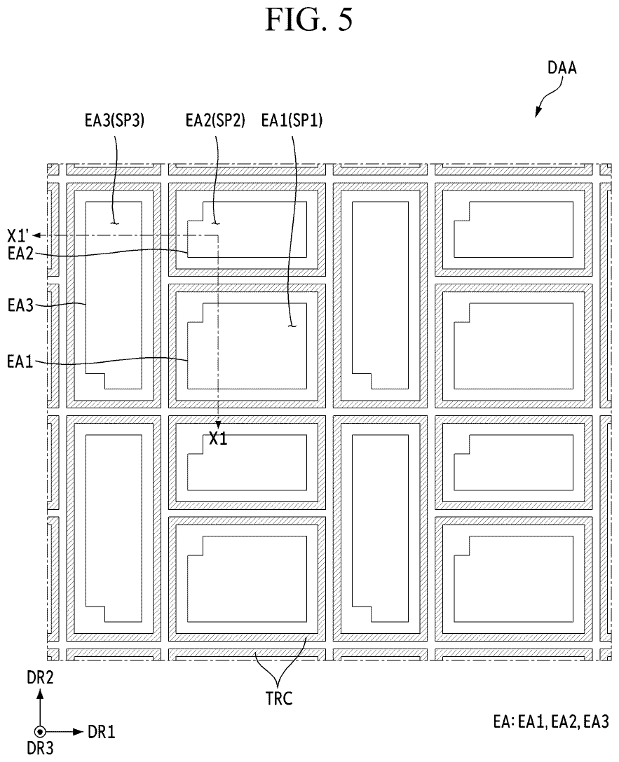

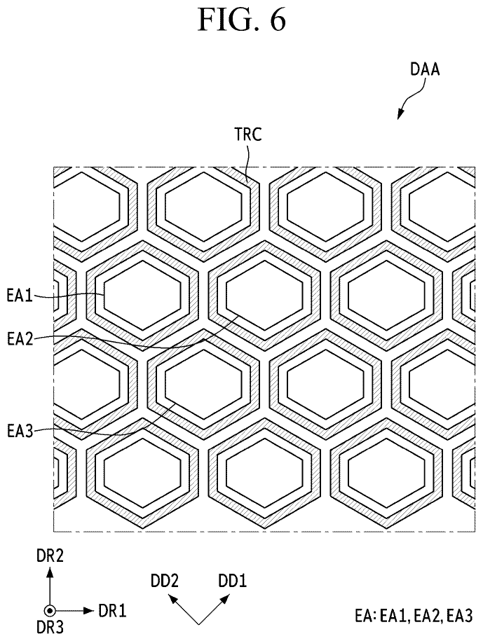

FIGS. 5 and 6 are schematic plan views showing an arrangement of multiple pixels in a display area of FIG. 4.

Referring to FIGS. 5 and 6, each of multiple pixels PX in a portion of overlapping the display area DAA may include a first emission area EA1 which is the emission area of the first sub-pixel SP1, a second emission area EA2 which is the emission area of the second sub-pixel SP2, and a third emission area EA3 which is the emission area of the third sub-pixel SP3.

The first emission area EA1 may emit light of a first color, the second emission area EA2 may emit light of a second color, and the third emission area EA3 may emit light of a third color. Here, the light of the first color may be light of a red wavelength band, the light of the second color may be light of a green wavelength band, and the light of the third color may be light of a blue wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band is a wavelength band of light whose main peak wavelength may be in the range of about 600 nm to about 750 nm.

The emission area EA may have a stripe structure aligned in the first and second directions DR1 and DR2 and a PenTile® structure having a diamond arrangement as illustrated in FIG. 5, or a hexagonal structure having a hexagonal shape in a plan view as illustrated in FIG. 6. However, the disclosure is not limited thereto, and the emission area EA may have different structure in which a polygonal shape, a circular shape, an elliptical shape, or an atypical shape is arranged in a plan view other than the described structure arrangement.

In some embodiments, in case that the emission area EA has a stripe structure, the first emission area EA1 and the second emission area EA2 may be disposed adjacent to each other in the second direction DR2, and the first emission area EA1 and the third emission area EA3 may be disposed adjacent to each other and the second emission area EA2 and the third emission area EA3 may be disposed adjacent to each other in the first direction DR1. The area of the first emission area EA1, the area of the second emission area EA2, and the area of the third emission area EA3 may be different.

In some embodiments, in case that the emission area EA has a hexagonal structure, the first emission area EA1 and the second emission area EA2 may be adjacent in the first direction DR1, but the second emission area EA2 and the third emission area EA3 may be adjacent in a first diagonal direction DD1, and the first emission area EA1 and the third emission area EA3 may be adjacent in a second diagonal direction DD2. At this time, the first diagonal direction DD1 intersects each of the first direction DR1 and the second direction DR2 as horizontal directions. For example, the first diagonal direction DD1 may be a direction inclined by 45 degrees with respect to the first direction DR1 and the second direction DR2, but the disclosure is not limited thereto. The second diagonal direction DD2 intersects each of the first direction DR1 and the second direction DR2 as horizontal directions. For example, the second diagonal direction DD2 may be a direction inclined by 45 degrees with respect to the opposite direction of the first direction DR1 and the second direction DR2, but the disclosure is not limited thereto. The second diagonal direction DD2 may be a direction perpendicular to the first diagonal direction DD1.

It is exemplified in FIGS. 5 and 6 that each of multiple pixels PX includes three emission areas EA1, EA2, and EA3, but the embodiment of the disclosure is not limited thereto. According to an embodiment, each of multiple pixels PX may include four or more emission areas.

Each emission area EA including multiple pixels PX may be surrounded by each trench TRC. The trench TRC will be described below.

FIG. 7 is a schematic cross-sectional view illustrating an example of a display panel taken along line X1-X1′ of FIG. 5.

Referring to FIG. 7, the display panel 100 may include a semiconductor backplane SBP, a light emitting element backplane EBP disposed on the semiconductor backplane SBP, a display element layer EML disposed on the light emitting element backplane EBP, an encapsulation layer TFE disposed on the display element layer EML, an optical layer OPL disposed on the encapsulation layer TFE, a cover layer CVL disposed on the optical layer OPL, and a polarizing plate POL disposed on the cover layer CVL.

The semiconductor backplane SBP may include the semiconductor substrate SSUB including multiple pixel transistors PTR, multiple semiconductor insulating films covering multiple pixel transistors PTR, and multiple contact terminals CTE electrically connected to multiple pixel transistors PTR, respectively. Multiple pixel transistors PTR may be the first to sixth transistors T1 to T6 described with reference to FIG. 3.

The semiconductor substrate SSUB may be replaced with a glass substrate or a polymer resin substrate such as polyimide. For example, thin film transistors may be disposed on the glass substrate or the polymer resin substrate. The glass substrate may be a rigid substrate that does not bend, and the polymer resin substrate may be a flexible substrate that can be bent or curved.

The semiconductor substrate SSUB may be a substrate doped with first type impurities. Multiple well regions WA may be disposed on the top surface of the semiconductor substrate SSUB. Multiple well regions WA may be regions doped with a second type impurity. The second type impurity may be different from the aforementioned first type impurity. For example, in case that the first type impurity is a p-type impurity, the second type impurity may be an n-type impurity. In another embodiment, in case that the first type impurity is an n-type impurity, the second type impurity may be a p-type impurity.

Each of multiple well regions WA may include a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on a side of the gate electrode GE, and the drain region DA may be disposed on another side of the gate electrode GE.

Each of multiple well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase so that punch-through and hot carrier phenomena that might be caused by a short channel are prevented.

A first semiconductor insulating film SINS1 may be disposed on the semiconductor substrate SSUB. The first semiconductor insulating film SINS1 may be formed of silicon carbonitride (SiCN) or a silicon oxide (SiOₓ)-based inorganic film, but the embodiment of the disclosure is not limited thereto.

A second semiconductor insulating film SINS2 may be disposed on the first semiconductor insulating film SINS1. The second semiconductor insulating film SINS2 may be formed of a silicon oxide (SiOₓ)-based inorganic film, but the embodiment of the disclosure is not limited thereto.

Multiple contact terminals CTE may be disposed on the second semiconductor insulating film SINS2. Each of multiple contact terminals CTE may be electrically connected to any one of the gate electrode GE, the source region SA, and the drain region DA of each of the pixel transistors PTR through holes penetrating the first semiconductor insulating film SINS1 and the second semiconductor insulating film SINS2. Multiple contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be disposed on a side surface of each of multiple contact terminals CTE. The top surface of each of multiple contact terminals CTE may be exposed without being covered by the third semiconductor insulating film SINS3. The third semiconductor insulating film SINS3 may be formed of a silicon oxide (SiOₓ)-based inorganic film, but the embodiment of the disclosure is not limited thereto.

The light emitting element backplane EBP may include multiple conductive layers ML1 to ML8, multiple vias VA1 to VA9, and multiple insulating films INS1 to INS9.

The first to eighth conductive layers ML1 to ML8 may serve to connect multiple contact terminals CTE exposed from the semiconductor backplane SBP to thereby implement the pixel circuit of the first sub-pixel SP1 shown in FIG. 3. For example, the first to sixth transistors T1 to T6 may be merely disposed on the semiconductor backplane SBP, and the connection line of the first to sixth transistors T1 to T6 and the first capacitor CP1 and the second capacitor CP2 may be disposed in the first to eighth conductive layers ML1 to ML8. A connection portion between the drain region corresponding to the drain electrode of the fourth transistor T4, the source region corresponding to the source electrode of the fifth transistor T5, and the first electrode of the light emitting element LE may also be disposed in the first to eighth conductive layers ML1 to ML8.

The first insulating film INS1 may be disposed on the semiconductor backplane SBP. Each of the first vias VA1 may penetrate the first insulating film INS1 and be electrically connected to the contact terminal CTE exposed from the semiconductor backplane SBP. Each of the first conductive layers ML1 may be disposed on the first insulating film INS1 and may be electrically connected to the first via VA1.

The second insulating film INS2 may be disposed on the first insulating film INS1 and the first conductive layers ML1. Each of the second vias VA2 may penetrate the second insulating film INS2 and be electrically connected to the exposed first conductive layer ML1. Each of the second conductive layers ML2 may be disposed on the second insulating film INS2 and may be electrically connected to the second via VA2.

The third insulating film INS3 may be disposed on the second insulating film INS2 and the second conductive layers ML2. Each of the third vias VA3 may penetrate the third insulating film INS3 and be electrically connected to the exposed second conductive layer ML2. Each of the third conductive layers ML3 may be disposed on the third insulating film INS3 and may be electrically connected to the third via VA3.

A fourth insulating film INS4 may be disposed on the third insulating film INS3 and the third conductive layers ML3. Each of the fourth vias VA4 may penetrate the fourth insulating film INS4 and be electrically connected to the exposed third conductive layer ML3. Each of the fourth conductive layers ML4 may be disposed on the fourth insulating film INS4 and may be electrically connected to the fourth via VA4.

A fifth insulating film INS5 may be disposed on the fourth insulating film INS4 and the fourth conductive layers ML4. Each of the fifth vias VA5 may penetrate the fifth insulating film INS5 and be electrically connected to the exposed fourth conductive layer ML4. Each of the fifth conductive layers ML5 may be disposed on the fifth insulating film INS5 and may be electrically connected to the fifth via VA5.

A sixth insulating film INS6 may be disposed on the fifth insulating film INS5 and the fifth conductive layers ML5. Each of the sixth vias VA6 may penetrate the sixth insulating film INS6 and be electrically connected to the exposed fifth conductive layer ML5. Each of the sixth conductive layers ML6 may be disposed on the sixth insulating film INS6 and may be electrically connected to the sixth via VA6.

A seventh insulating film INS7 may be disposed on the sixth insulating film INS6 and the sixth conductive layers ML6. Each of the seventh vias VA7 may penetrate the seventh insulating film INS7 and be electrically connected to the exposed sixth conductive layer ML6. Each of the seventh conductive layers ML7 may be disposed on the seventh insulating film INS7 and may be electrically connected to the seventh via VA7.

An eighth insulating film INS8 may be disposed on the seventh insulating film INS7 and the seventh conductive layers ML7. Each of the eighth vias VA8 may penetrate the eighth insulating film INS8 and be electrically connected to the exposed seventh conductive layer ML7. Each of the eighth conductive layers ML8 may be disposed on the eighth insulating film INS8 and may be electrically connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. First to eighth insulating films INS1 to INS8 may be formed of a silicon oxide (SiOₓ)-based inorganic film, but the embodiment of the disclosure is not limited thereto.

The thicknesses of the first conductive layer ML1, the second conductive layer ML2, the third conductive layer ML3, the fourth conductive layer ML4, the fifth conductive layer ML5, and the sixth conductive layer ML6 in the third direction DR3 (or thickness direction) may be greater than the thicknesses of the first via VA1, the second via VA2, the third via VA3, the fourth via VA4, the fifth via VA5, and the sixth via VA6 in the third direction DR3 (or thickness direction), respectively. The thickness of each of the second conductive layer ML2, the third conductive layer ML3, the fourth conductive layer ML4, the fifth conductive layer ML5, and the sixth conductive layer ML6 in the third direction DR3 (or thickness direction) may be greater than the thickness of the first conductive layer ML1 in the third direction DR3 (or thickness direction). The thickness of the second conductive layer ML2, the thickness of the third conductive layer ML3, the thickness of the fourth conductive layer ML4, the thickness of the fifth conductive layer ML5, and the thickness of the sixth conductive layer ML6 in the third direction DR3 (or thickness direction) may be substantially the same. For example, the thickness of the first conductive layer ML1 may be about 1360 Å. The thickness of each of the second conductive layer ML2, the third conductive layer ML3, the fourth conductive layer ML4, the fifth conductive layer ML5, and the sixth conductive layer ML6 may be about 1440 Å. The thickness of each of the first via VA1, the second via VA2, the third via VA3, the fourth via VA4, the fifth via VA5, and the sixth via VA6 may be about 1150 Å. However, the thicknesses of the first to sixth conductive layers ML1, ML2, ML3, ML4, ML5, and ML6 and the first to sixth vias VA1, VA2, VA3, VA4, VA5, and VA6 are not limited thereto.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6 in the third direction DR3 (or thickness direction). The thickness of the seventh conductive layer ML7 and the thickness of the eighth conductive layer ML8 may be greater than the thickness of the seventh via VA7 and the thickness of the eighth via VA8 in the third direction DR3 (or thickness direction), respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6 in the third direction DR3 (or thickness direction). The thickness of the seventh conductive layer ML7 and the thickness of the eighth conductive layer ML8 in the third direction DR3 (or thickness direction) may be substantially the same. For example, the thickness of each of the seventh conductive layer ML7 and the eighth conductive layer ML8 may be about 9000 Å, and the thickness of each of the seventh via VA7 and the eighth via VA8 may be about 6000 Å. However, the thicknesses of the seventh conductive layer ML7, the eighth conductive layer ML8, the seventh via VA7, and the eighth via VA8 are not limited thereto.

A ninth insulating film INS9 may be disposed on the eighth insulating film INS8 and the eighth conductive layer ML8. The ninth insulating film INS9 may be formed of a silicon oxide (SiOₓ)-based inorganic film, but the embodiment of the disclosure is not limited thereto.

Each of the ninth vias VA9 may penetrate the ninth insulating film INS9 and be electrically connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

The display element layer EML may be disposed on the light emitting element backplane EBP. The display element layer EML may include light emitting elements LE, a pixel defining film PDL, and multiple trenches TRC. Each light emitting element LE may include a reflective electrode layer RL, tenth and eleventh insulating films INS10 and INS11, a tenth via VA10, a first electrode AND, a light emitting layer IL, and a second electrode CAT.

The reflective electrode layer RL may be disposed on the ninth insulating film INS9. The reflective electrode layer RL may include at least one reflective electrode RL1, RL2, RL3, and RL4. For example, the reflective electrode layer RL may include first to fourth reflective electrodes RL1, RL2, RL3, and RL4 as shown in FIG. 7, but is not limited thereto.

Each of the first reflective electrodes RL1 may be disposed on the ninth insulating film INS9, and may be electrically connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN).

Each of the second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the second reflective electrodes RL2 may include aluminum (Al).

Each of the third reflective electrodes RL3 may be disposed on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the third reflective electrodes RL3 may include titanium nitride (TiN).

Each of the fourth reflective electrodes RL4 may be disposed on the third reflective electrode RL3. The fourth reflective electrodes RL4 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the fourth reflective electrodes RL4 may include titanium (Ti).

Since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4 in the third direction DR3 (or thickness direction). For example, the thickness of each of the first reflective electrode RL1, the third reflective electrode RL3, and the fourth reflective electrode RL4 may be about 100 Å, and the thickness of the second reflective electrode RL2 may be about 850 Å. However, the thicknesses of the first to fourth reflective electrodes RL1, RL2, RL3, and RL4 are not limited thereto.

The tenth insulating film INS10 may be disposed on the ninth insulating film INS9. The tenth insulating film INS10 may be disposed between the reflective electrode layers RL disposed adjacent to each other in a horizontal direction. The tenth insulating film INS10 may be formed of a silicon oxide (SiOₓ)-based inorganic film, but the embodiment of the disclosure is not limited thereto. Although not shown in the drawing, the tenth insulating film INS10 may be disposed not only between the reflective electrode layers RL but also on the reflective electrode layer RL.

The eleventh insulating film INS11 may be disposed on the tenth insulating film INS10 and the reflective electrode layer RL. The eleventh insulating film INS11 may be formed of a silicon oxide (SiOₓ)-based inorganic film, but the embodiment of the disclosure is not limited thereto. The tenth insulating film INS10 and the eleventh insulating film INS11 may be an optical auxiliary layer through which light reflected by the reflective electrode layer RL passes, among light emitted from the light emitting elements LE.

In some embodiments, in at least any one sub-pixel among the first sub-pixel SP1, the second sub-pixel SP2, and the third sub-pixel SP3, in order to adjust the resonance distance of light emitted from the light emitting elements LE, the total thickness of the insulating film disposed between the first electrode AND and the reflective electrode layer RL may be different in the first sub-pixel SP1, the second sub-pixel SP2, and the third sub-pixel SP3.

As shown in the drawing, in case that the tenth insulating film INS10 is not disposed between the first electrode AND and the reflective electrode layer RL but the eleventh insulating film INS11 is disposed therebetween, the thickness of the eleventh insulating film INS11 disposed in each of the first sub-pixel SP1, the second sub-pixel SP2, and the third sub-pixel SP3 in the third direction DR3 (or thickness direction) may be different. For example, the thickness of the eleventh insulating film INS11 disposed in the first sub-pixel SP1 may be smaller than the thickness of the eleventh insulating film INS11 disposed in the second sub-pixel SP2 in the third direction DR3 (or thickness direction), and the thickness of the eleventh insulating film INS11 disposed in the second sub-pixel SP2 may be smaller than the thickness of the eleventh insulating film INS11 disposed in the third sub-pixel SP3 in the third direction DR3 (or thickness direction).

In another embodiment, in the first sub-pixel SP1, neither the tenth insulating film INS10 nor the eleventh insulating film INS11 may be disposed between the first electrode AND and the reflective electrode layer RL, and in the second sub-pixel SP2, any one of the tenth insulating film INS10 and the eleventh insulating film INS11 may be disposed between the first electrode AND and the reflective electrode layer RL, and in the third sub-pixel SP3, both the tenth insulating film INS10 and the eleventh insulating film INS11 may be disposed between the first electrode AND and the reflective electrode layer RL.

In another embodiment, a twelfth insulating film may be further disposed between the first electrode AND and the reflective electrode layer RL. For example, in the first sub-pixel SP1, any one of the tenth insulating film INS10, the eleventh insulating film INS11, and the twelfth insulating film may be disposed between the first electrode AND and the reflective electrode layer RL, in the second sub-pixel SP2, any two of the tenth insulating film INS10, the eleventh insulating film INS11, and the twelfth insulating film may be disposed between the first electrode AND and the reflective electrode layer RL, and in the third sub-pixel SP3, all the tenth insulating film INS10, the eleventh insulating film INS11, and the twelfth insulating film may be disposed between the first electrode AND and the reflective electrode layer RL.

Thus, the distance between the first electrode AND and the reflective electrode layer RL may be different in the first sub-pixel SP1, the second sub-pixel SP2, and the third sub-pixel SP3. For example, in order to adjust the distance from the reflective electrode layer RL to the second electrode CAT according to the main wavelength of the light emitted from each of the first sub-pixel SP1, the second sub-pixel SP2, and the third sub-pixel SP3, the presence/absence or thickness of the tenth insulating film INS10 and the eleventh insulating film INS11 may be set in each of the first sub-pixel SP1, the second sub-pixel SP2, and the third sub-pixel SP3.

Although it is illustrated in the drawing that the total thickness of the insulating film disposed between the first electrode AND and the reflective electrode layer RL increases in the order of the first sub-pixel SP1, the second sub-pixel SP2, and the third sub-pixel SP3, the disclosure is not limited thereto. For example, the distance between the first electrode AND and the reflective electrode layer RL in the third sub-pixel SP3 may be greater than the distance between the first electrode AND and the reflective electrode layer RL in the second sub-pixel SP2 and the distance between the first electrode AND and the reflective electrode layer RL in the first sub-pixel SP1, and the distance between the first electrode AND and the reflective electrode layer RL in the second sub-pixel SP2 may be greater than the distance between the first electrode AND and the reflective electrode layer RL in the first sub-pixel SP1, but the embodiment of the disclosure is not limited thereto. The size relationship of the total thickness of the insulating film disposed between the first electrode AND and the reflective electrode layer RL in each of the first sub-pixel SP1, the second sub-pixel SP2, and the third sub-pixel SP3 may be variously changed depending on the resonance distance.

Each of the tenth vias VA10 may be electrically connected to a ninth conductive layer ML9 exposed through the tenth insulating film INS10 and/or the eleventh insulating film INS11. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the second sub-pixel SP2 may be less than the thickness of the tenth via VA10 in the third sub-pixel SP3, and the thickness of the tenth via VA10 in the first sub-pixel SP1 may be less than the thickness of the tenth via VA10 in the second sub-pixel SP2, but the disclosure is not limited thereto.

The first electrode AND of each of the light emitting elements LE may be disposed on the eleventh insulating film INS11 and electrically connected to the tenth via VA10. The first electrode AND of each of the light emitting elements LE may be electrically connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

The pixel defining film PDL may be disposed on a part of the first electrode AND of each of the light emitting elements LE. The pixel defining film PDL may cover the edge of the first electrode AND of each of the light emitting elements LE. The pixel defining film PDL may serve to partition each of the first emission areas EA1, the second emission areas EA2, and the third emission areas EA3.

The first emission area EA1 may be defined as an area in which the first electrode AND, the light emitting layer IL, and the second electrode CAT are sequentially stacked in the first sub-pixel SP1 to emit light. The second emission area EA2 may be defined as an area in which the first electrode AND, the light emitting layer IL, and the second electrode CAT are sequentially stacked in the second sub-pixel SP2 to emit light. The third emission area EA3 may be defined as an area in which the first electrode AND, the light emitting layer IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOₓ)-based inorganic film, but the embodiment of the disclosure is not limited thereto. The first pixel defining film PDL1, the second pixel defining film PDL2, and the third pixel defining film PDL3 may each have a thickness of about 500 Å.

In case that the first pixel defining film PDL1, the second pixel defining film PDL2, and the third pixel defining film PDL3 are formed as one pixel defining film, the height of the pixel defining film increases so that a first encapsulation layer TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to reduce or prevent the likelihood of the first encapsulation layer TFE1 being cut off due to the step coverage, the first pixel defining film PDL1, the second pixel defining film PDL2, and the third pixel defining film PDL3 may have a cross-sectional structure having a stepped portion. For example, the width of the first pixel defining film PDL1 may be greater than the width of the second pixel defining film PDL2 and the width of the third pixel defining film PDL3, and the width of the second pixel defining film PDL2 may be greater than the width of the third pixel defining film PDL3. Each of the width of the first pixel defining film PDL1, the width of the second pixel defining film PDL2, and the width of the third pixel defining film PDL3 refers to the length in the horizontal direction perpendicular to the third direction DR3.

Each of multiple trenches TRC may penetrate the first pixel defining film PDL1, the second pixel defining film PDL2, and the third pixel defining film PDL3. Furthermore, each of multiple trenches TRC may penetrate the eleventh insulating film INS11. The eleventh insulating film INS11 may be partially recessed at each of multiple trenches TRC.

At least one trench TRC may be disposed between the neighboring first to third sub-pixels SP1, SP2, and SP3. Although FIG. 7 illustrates that two trenches TRC are disposed between the neighboring first to third sub-pixels SP1, SP2, and SP3, the disclosure is not limited thereto.

The light emitting layer IL may include multiple stacked layers. FIG. 7 illustrates that the light emitting layer IL has a three-tandem structure including a first stack layer IL1, a second stack layer IL2, and a third stack layer IL3, but the embodiment of the disclosure is not limited thereto. For example, the light emitting layer IL may have a two-tandem structure including two stacked layers.

In the three-tandem structure, the light emitting layer IL may have a tandem structure including multiple first to third stack layers IL1, IL2, and IL3 that emit different lights. For example, the light emitting layer IL may include the first stack layer IL1 that emits light of the first color, the second stack layer IL2 that emits light of the third color, and the third stack layer IL3 that emits light of the second color. The first stack layer IL1, the second stack layer IL2, and the third stack layer IL3 may be sequentially stacked.

The first stack layer IL1 may have a structure in which a first hole transport layer, a first organic light emitting layer that emits light of the first color, and a first electron transport layer are sequentially stacked. The second stack layer IL2 may have a structure in which a second hole transport layer, a second organic light emitting layer that emits light of the third color, and a second electron transport layer are sequentially stacked. The third stack layer IL3 may have a structure in which a third hole transport layer, a third organic light emitting layer that emits light of the second color, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and may be disposed on the bottom surface of each trench TRC. Due to the trench TRC, the first stack layer IL1 may be cut off between the neighboring first to third sub-pixels SP1, SP2, and SP3. The second stack layer IL2 may be disposed on the first stack layer IL1. Due to the trench TRC, the second stack layer IL2 may be cut off between the neighboring sub-pixels SP1, SP2, and SP3. A cavity ESS or an empty space may be disposed between the first stack layer IL1 and the second stack layer IL2. The third stack layer IL3 may be disposed on the second stack layer IL2. The third stack layer IL3 may not be cut off by the trench TRC and may be disposed to cover the second stack layer IL2 in each of the trenches TRC. For example, in the three-tandem structure, each of multiple trenches TRC may be a structure for cutting off the first and second stack layers IL1 and IL2, the first charge generation layer, and the second charge generation layer of the display element layer EML between the first to third sub-pixels SP1, SP2, and SP3 disposed adjacent to each other. In the two-tandem structure, each of the trenches TRC may be a structure for cutting off the charge generation layer disposed between a lower intermediate layer and an upper intermediate layer, and the lower intermediate layer.

The height of each of multiple trenches TRC in the third direction DR3 (or thickness direction) may be greater than the height of the pixel defining film PDL. This may be for stably cutting off the first and second stack layers IL1 and IL2 of the display element layer EML between adjacent sub-pixels SP1, SP2, and SP3.

The height of each of multiple trenches TRC refers to the length of each of multiple trenches TRC in the third direction DR3. The height of the pixel defining film PDL refers to the length of the pixel defining film PDL in the third direction DR3. In order to cut off the first to third stack layers IL1, IL2, and IL3 of the display element layer EML between the neighboring sub-pixels SP1, SP2, and SP3, another structure may exist instead of the trench TRC. For example, instead of the trench TRC, a reverse tapered partition wall may be disposed on the pixel defining film PDL.

The number of the first to third stack layers IL1, IL2, and IL3 that emit different lights is not limited to that shown in FIG. 7. For example, the light emitting layer IL may include two stack layers. For example, one of the two stack layers may be substantially the same as the first stack layer IL1, and another may include a second hole transport layer, a second organic light emitting layer, a third organic light emitting layer, and a second electron transport layer. For example, a charge generation layer for supplying electrons to a stack layer and supplying charges to another stack layer may be disposed between the two stack layers.

FIG. 7 illustrates that the first to third stack layers IL1, IL2, and IL3 are all disposed in the first emission area EA1, the second emission area EA2, and the third emission area EA3, but the embodiment of the disclosure is not limited thereto. For example, the first stack layer IL1 may be disposed in the first emission area EA1, and may be omitted from the second emission area EA2 and the third emission area EA3. Furthermore, the second stack layer IL2 may be disposed in the second emission area EA2 and may be omitted from the first emission area EA1 and the third emission area EA3. The third stack layer IL3 may be disposed in the third emission area EA3 and may be omitted from the first emission area EA1 and the second emission area EA2. For example, first to third color filters CF1, CF2, and CF3 of the optical layer OPL may be omitted.

The second electrode CAT may be disposed on the third stack layer IL3. The second electrode CAT may be disposed on the third stack layer IL3 in each of multiple trenches TRC.

The second electrode CAT may be formed of a transparent conductive material (TCO) such as ITO or IZO that can transmit light or a semi-transmissive conductive material such as magnesium (Mg), silver (Ag), or an alloy of Mg and Ag. In case that the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE2 to reduce or prevent oxygen or moisture from permeating into the display element layer EML. For example, the encapsulation layer TFE may include a first encapsulation layer TFE1, and a second encapsulation layer TFE2.

The first encapsulation layer TFE1 may be disposed on the second electrode CAT. The first encapsulation layer TFE1 may be formed as a multilayer in which one or more inorganic films selected from silicon nitride (SiNₓ), silicon oxy nitride (SiON), and silicon oxide (SiOₓ) are alternately stacked. The first encapsulation layer TFE1 may be formed by a chemical vapor deposition (CVD) process.

The second encapsulation layer TFE2 may be disposed on the first encapsulation layer TFE1. The second encapsulation layer TFE2 may be formed of titanium oxide (TiOₓ) or aluminum oxide (AlOₓ), but the embodiment of the disclosure is not limited thereto. The second encapsulation layer TFE2 may be formed by an atomic layer deposition (ALD) process. The thickness of the second encapsulation layer TFE2 may be less than the thickness of the first encapsulation layer TFE1.

The display panel 100 may further include an organic film APL. An organic film APL may be a layer for increasing the interfacial adhesion disposed between the encapsulation layer TFE and the optical layer OPL.

The organic film APL may be an organic film such as acrylic resin, epoxy resin, phenolic resin, polyamide resin, or polyimide resin.

The optical layer OPL may include multiple first to third color filters CF1, CF2, and CF3, multiple lenses LNS, and a filling layer FIL.

The first to third color filters CF1, CF2, and CF3 may be disposed on the organic film APL.

The first color filter CF1 may overlap the first emission area EA1 of the first sub-pixel SP1. The first color filter CF1 may transmit light of the first color, i.e., light of a red wavelength band. The red wavelength band may be about 600 nm to about 750 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, i.e., light of a green wavelength band. The green wavelength band may be about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, i.e., light of a blue wavelength band. The blue wavelength band may be about 370 nm to about 460 nm. Thus, the third color filter CF3 may transmit light of the third color among light emitted from the third emission area EA3.

Multiple lenses LNS may be disposed on the first color filter CF1, the second color filter CF2, and the third color filter CF3, respectively. Each of multiple lenses LNS may be a structure for increasing the proportion of light directed to the front of the display device 10. Each of multiple lenses LNS may have a cross-sectional shape that is convex in an upward direction. Multiple lenses LNS may be a micro lens array (MLA).

The filling layer FIL may be disposed on multiple lenses LNS. The filling layer FIL may have a predetermined refractive index such that light travels in the third direction DR3 at an interface between the filling layer FIL and multiple lenses LNS. The filling layer FIL may be a planarization layer. The filling layer FIL may be an organic film such as acrylic resin, epoxy resin, phenolic resin, polyamide resin, or polyimide resin.

The cover layer CVL may be disposed on the filling layer FIL. The cover layer CVL may be a glass substrate or a polymer resin. In case that the cover layer CVL is a glass substrate, it may be attached onto the filling layer FIL. For example, the filling layer FIL serves to bond the cover layer CVL. In case that the cover layer CVL is a glass substrate, it may serve as an encapsulation substrate. In case that the cover layer CVL is a polymer resin, it may be applied (or directly applied) onto the filling layer FIL.

The polarizing plate POL may be disposed on one surface of the cover layer CVL. The polarizing plate POL may be a structure for reducing or preventing visibility degradation caused by reflection of external light. The polarizing plate POL may include a linear polarizing plate and a phase retardation film. For example, the phase retardation film may be a λ/4 plate (quarter-wave plate), but the embodiment of the disclosure is not limited thereto. However, in case that visibility degradation caused by reflection of external light is sufficiently overcome by the first to third color filters CF1, CF2, and CF3, the polarizing plate POL may be omitted.

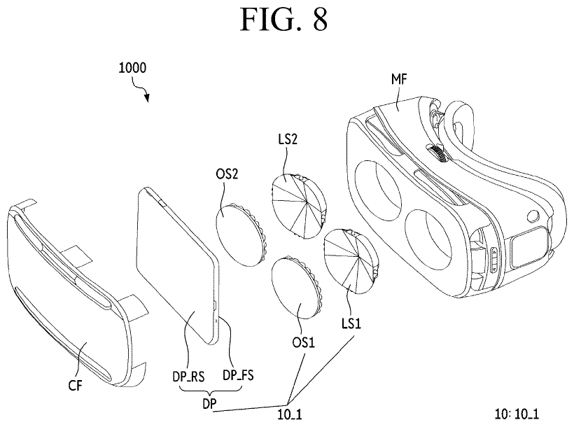

FIG. 8 is an exploded schematic perspective view illustrating a head mounted display according to an embodiment.

Referring to FIG. 8, a head mounted display 1000 may be formed in the form of glasses or a head mount to provide an image to a user using a display device 10_1.

The head mounted display 1000 may include a see-through type that provides augmented reality based on actual external objects and a see-closed type that provides virtual reality to the user on a screen independent from the external objects.

The head mounted display 1000 may include a main frame MF mounted on the user's body, the display device 10_1 mounted on the main frame MF to display an image, and a cover frame CF that covers the display device 10_1.

The display device 10_1 may be formed integrally with the head mounted display 1000 that may be carried by the user and easily attached to or detached from a face or a head, and may be formed to be assembled to the head mounted display 1000. The display device 10_1 may be substantially the same as the display device 10 described in conjunction with FIG. 1 and the like.

The display device 10_1 may include a display panel DP that displays an image, first and second lens frames OS1 and OS2 that refract an image display light, and first and second multi-channel lenses LS1 and LS2 that form an optical path so that the image display light of the display panel DP is visible to the user.

The main frame MF may be worn on the user's face and head. The main frame MF may be formed in a shape corresponding to the user's head and facial structure.

The main frame MF may be integrally formed with display device 10_1, for example, the display panel DP, the first and second lens frames OS1 and OS2, and the first and second multi-channel lenses LS1 and LS2. In another embodiment, the display panel DP, the first and second lens frames OS1 and OS2, and the first and second multi-channel lenses LS1 and LS2 may be assembled and mounted to the main frame MF. To this end, the main frame MF may have a space or a structure for accommodating the display panel DP, the first and second lens frames OS1 and OS2, and the first and second multi-channel lenses LS1 and LS2. The main frame MF may further include a structure such as a strap or a band to facilitate the mounting, and a controller, an image processing unit, and a lens accommodating unit may be further included in the main frame MF.

The display panel DP may be divided into a front surface DP_FS where an image is displayed, and a rear surface DP_RS located on the opposite side of the front surface DP_FS. Image display light may be emitted from the front surface DP_FS of the display panel DP. As will be described later, the first and second lens frames OS1 and OS2 may be disposed on the front surface DP_FS of the display panel DP, and the first and second multi-channel lenses LS1 and LS2 may be disposed on the front surfaces of the first and second lens frames OS1 and OS2. Meanwhile, although not shown, at least one infrared camera may be disposed on at least one of the front surface DP_FS or the rear surface DP_RS of the display panel DP. The display panel DP may be substantially the same as the display panel 100 described in conjunction with FIG. 1 and the like.

The display panel DP may be built in the main frame MF in a state where the first and second lens frames OS1 and OS2 and the first and second multi-channel lenses LS1 and LS2 are mounted and fixed, or may be detachably assembled to the main frame MF. The display panel DP may be opaque, transparent, or translucent depending on the design of the display device 10_1, for example, the usage type of the display device 10_1.

Each of the first and second lens frames OS1 and OS2 may have an area corresponding to the image display surface of the display panel DP, and may be formed in a shape corresponding to that of the image display surface. The first and second lens frames OS1 and OS2 may be formed to have an area and a shape corresponding to those of the rear surfaces of the first and second multi-channel lenses LS1 and LS2, respectively. The rear surfaces of the first and second lens frames OS1 and OS2 may be attached to the image display surface of the display panel DP, and the first and second multi-channel lenses LS1 and LS2 may be attached to the front surfaces of the first and second lens frames OS1 and OS2, respectively. The first and second lens frames OS1 and OS2 refract the image display light emitted from the image display surface of the display panel DP at a preset angle and provide it to the first and second multi-channel lenses LS1 and LS2 disposed on the front surfaces thereof, respectively.

For example, the first and second lens frames OS1 and OS2 may refract the image display light, which is emitted from the image display surface of the display panel DP toward the front side, toward an outer side (or toward an outer peripheral side) compared to the front side and provide it to the first and second multi-channel lenses LS1 and LS2 disposed on the front surfaces thereof, respectively. In particular, the first and second lens frames OS1 and OS2 may refract the image display light incident on the rear surfaces thereof toward the outer side (or toward the outer peripheral side) and provide it to the rear surfaces of the first and second multi-channel lenses LS1 and LS2, respectively.

The first and second multi-channel lenses LS1 and LS2 may form a path for light emitted through the first and second lens frames OS1 and OS2 so that the image display light is visible to the user's eyes on the front side.

The first and second multi-channel lenses LS1 and LS2 may provide multiple channels (or paths) through which the image display light emitted from the display panel DP passes. Multiple channels may provide the image display light emitted from the display panel DP to the user through different paths. The image display light emitted through the first and second lens frames OS1 and OS2 may be incident on the respective channels, and the image magnified through the respective channels may be focused on the user's eyes.

The first and second multi-channel lenses LS1 and LS2 may be respectively arranged on the front surfaces the first and second lens frames OS1 and OS2 to correspond to the positions of the user's left eye and right eye. The first and second multi-channel lenses LS1 and LS2 may be accommodated in the main frame MF.

The first and second multi-channel lenses LS1 and LS2 may refract and/or reflect the image display light emitted through the first and second lens frames OS1 and OS2 at least once to form a path to the user's eyes. At least one infrared light source may be further disposed at the main frame MF, or on a side of each of the first and second multi-channel lenses LS1 and LS2 facing the user's eyes.

The cover frame CF may be disposed on the rear surface DP_RS of the display panel DP to cover the display panel DP and may protect the display panel DP. The cover frame CF may be attached to the main frame MF while covering the display panel DP.

Although not shown, the display device 10_1 may further include a controller for controlling the overall operation of the display device 10_1 including the display panel DP. The controller may control the image display operation of the display panel DP and audio devices. For example, the controller performs image processing (e.g., image mapping) according to the magnification ratio and the image display path corresponding to the first and second lens frames OS1 and OS2 and the first and second multi-channel lenses LS1 and LS2, and controls the mapped image to be displayed on the display panel DP. The controller may be implemented as a dedicated processor including an embedded processor and/or a general-purpose processor including a central processing unit or an application processor, but is not limited thereto.

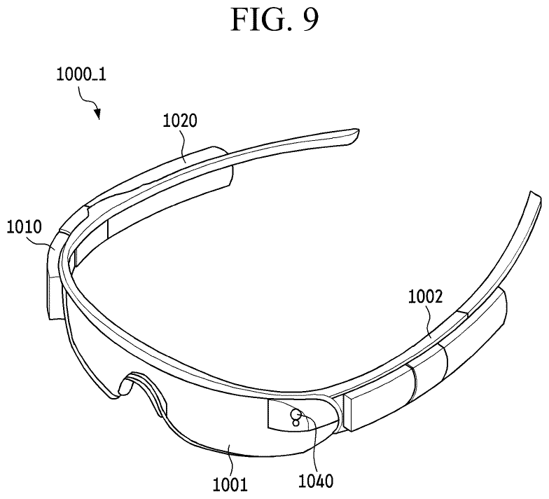

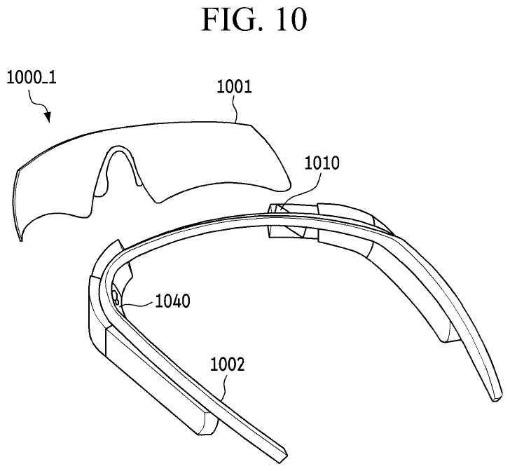

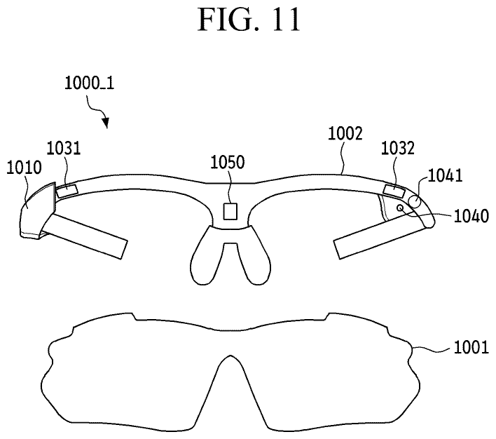

FIG. 9 is a schematic perspective view showing an augmented reality content providing device according to an embodiment. FIG. 10 is a rear exploded schematic perspective view of the augmented reality content providing device of FIG. 9, and FIG. 11 is a front exploded schematic perspective view of the augmented reality content providing device of FIG. 9.

Referring to FIGS. 9 to 11, an augmented reality content providing device 1000_1 may include a support frame 1002 supporting at least one transparent lens 1001, at least one image display module 1010, a surrounding environment detector 1040, and a control module 1020.

The support frame 1002 may be formed in the form of glasses including a spectacle frame supporting the edge of at least one transparent lens 1001 and spectacle frame legs. The shape of the support frame 1002 is not limited to a glasses type, and may be formed in a goggle type including the transparent lens 1001, or a head mount type.

The transparent lens 1001 may include left and right parts formed integrally, or first and second transparent lenses formed separately. The transparent lens 1001, which includes the integrated left and right parts or the separated first and second transparent lenses, may be made of glass or plastic that is transparent or translucent. Accordingly, the user can view the image of reality through the transparent lens 1001 that includes the integrated right and left parts or the separated first and second transparent lenses. Here, the transparent lens 1001, for example, the integrated lens or the first and second transparent lenses, may have a refractive power in consideration of the user's eyesight.

The transparent lens 1001 may further include at least one reflective member that reflects the augmented reality content image provided from the at least one image display module 1010 toward the transparent lens 1001 or the user's eyes, and optical members that adjust a focus and a size. One or more reflective member may be built in the transparent lens 1001 to be integrated with the transparent lens 1001, and may be formed as multiple refractive lenses or multiple prisms with a predetermined curvature.

The at least one image display module 1010 may include a micro LED display device (micro-LED), a nano LED display device (nano-LED), an organic light emitting display device (OLED), an inorganic light emitting display device (inorganic EL), a quantum dot light emitting display device (QED), a cathode ray display (CRT), a liquid crystal display (LCD), or the like. The image display module 1010 may substantially include the display device 10 described with reference to FIG. 1 and the like.

The surrounding environment detector 1040 may be assembled or integrally formed with the support frame 1002, and detects the distance (or depth) to an object on the front side of the support frame 1002, the illuminance, the moving direction of the support frame 1002, the moving distance, the tilt, or the like. To this end, the surrounding environment detector 1040 includes a depth sensor 1041 such as an infrared sensor or a LiDAR sensor, and an image sensor 1050 such as a camera. The surrounding environment detector 1040 may further include at least one motion sensor among an illumination sensor, a human body detection sensor, a gyro sensor, a tilt sensor, and an acceleration sensor. The surrounding environment detector 1040 may further include first and second biometric sensors 1031 and 1032 for detecting movement information of the user's eyes or pupils.

The surrounding environment detector 1040 may transmit sensing signals generated by the depth sensor 1041 and at least one motion sensor to the control module 1020 in real time. The image sensor 1050 may transmit image data in units of at least one frame generated in real time to the control module 1020. The first and second biometric sensors 1031 and 1032 of the surrounding environment detector 1040 may transmit the detected pupil detection signals to the control module 1020.

The control module 1020 may be assembled to at least one side of the support frame 1002 together with the at least one image display module 1010 or may be formed integrally with the support frame 1002. The control module 1020 supplies augmented reality content data to the at least one image display module 1010 so that the at least one image display module 1010 displays an augmented reality content, e.g., an augmented reality content image. At the same time, the control module 1020 may receive sensing signals, image data, and pupil detection signals from the surrounding environment detector 1040 in real time.

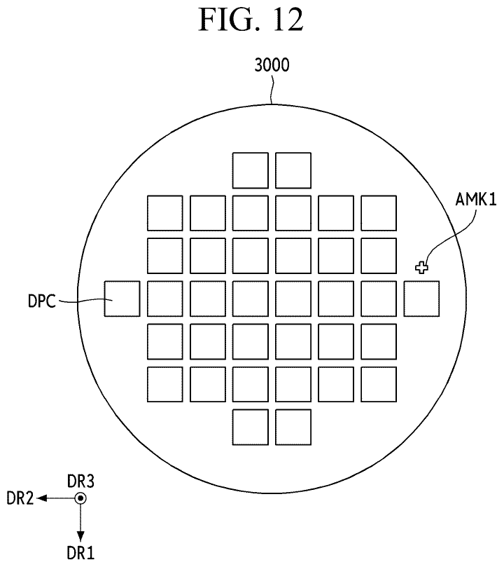

FIG. 12 is a schematic plan view showing a mother semiconductor substrate including a display cell according to an embodiment.

Referring to FIG. 12 in addition to FIGS. 1 to 11, a mother semiconductor substrate 3000 may be composed of a semiconductor wafer. The mother semiconductor substrate 3000 may contain a group IV material or a group III-V compound. The mother semiconductor substrate 3000 may be formed as a monocrystalline wafer. For example, the mother semiconductor substrate 3000 may be a silicon substrate, a germanium substrate, or a silicon-germanium substrate.

However, the mother semiconductor substrate 3000 is not limited to a single-crystal wafer, and may be any of various types of wafers such as an epi or epitaxial wafer, a polished wafer, an annealed wafer, and an SOI (silicon on insulator) wafer. An epitaxial wafer may be a wafer in which a crystalline material is grown on a single-crystal silicon substrate.

The mother semiconductor substrate 3000 may include a first alignment mark AMK1. The first alignment mark AMK1 will be described below.

The mother semiconductor substrate 3000 may include multiple display cells DPC. Multiple display cells DPC may be preprocessing components that form part of the display panel 100 described above. For example, the mother semiconductor substrate 3000 may form the semiconductor substrate SSUB of the display panel 100, and multiple display cells DPC may form the semiconductor backplane SBP, the display element layer EML, and an encapsulation layer TFE.

Multiple display cells DPC may be formed using a semiconductor apparatus or may be formed through a semiconductor process, but the disclosure is not limited thereto. The display panel 100 may be formed by forming multiple display cells DPC, and then cell-cutting in each display cell DPC units.

Although not shown in the drawing, each of the display cells DPC may include multiple pixels PX, and each of the pixels PX may include multiple light emitting elements. The light emitting layer IL included in the light emitting element may be formed through a deposition process. In general, in order to form the light emitting layer IL in the high-resolution display device 10 through a deposition process, a more precise deposition mask may be required. Hereinafter, a deposition mask for forming the high-resolution display device 10 will be described.

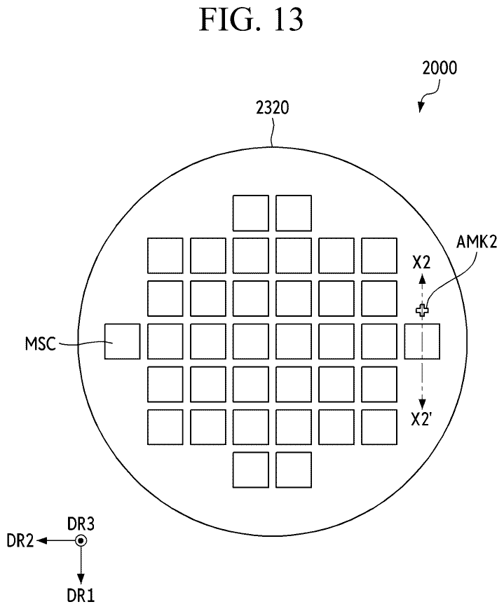

FIG. 13 is a schematic plan view showing a deposition mask including a mask cell according to an embodiment.

Referring to FIG. 13 in addition to FIGS. 1 to 12, a deposition mask 2000 according to an embodiment may be a deposition mask for use in manufacturing an ultra-high resolution display. As an example, the deposition mask 2000 may be a deposition mask for use in manufacturing a display included in the head mounted display device or an augmented reality content providing device.

The deposition mask 2000 may be used to perform a pixel deposition process on a silicon wafer. In general, in the case of a display included in an extended reality device, since a screen is positioned (or directly positioned) in front of the user's eyes, it may have a small screen rather than a large one. In addition, since the display is positioned close to the user's eyes, ultra-high resolution may be required. As an example, the required resolution of the display included in the extended reality device may be about 1000 PPI or more, and, desirably, an ultra-high resolution of 3000 PPI or more may be required. The deposition mask 2000 according to an embodiment may be a mask for use in manufacturing such an ultra-high resolution display. In another embodiment, the deposition mask 2000 may be a fine silicon mask (FSM).

The deposition mask 2000 may include a mask substrate 2320 and multiple mask cells MSC. The mask substrate 2320 may be located to surround each mask cell MSC.

The mask substrate 2320 may be composed of a semiconductor wafer. The mask substrate 2320 may contain a group IV material or a group III-V compound. The mask substrate 2320 may be composed of a monocrystalline wafer. For example, the mask substrate 2320 may be a silicon substrate, a germanium substrate, or a silicon-germanium substrate. However, the mask substrate 2320 is not limited to the monocrystalline wafer, and may be any of various types of wafers such as an epi or epitaxial wafer, a polished wafer, an annealed wafer, and an SOI (silicon on insulator) wafer. An epitaxial wafer is a wafer in which a crystalline material is grown on a monocrystalline substrate.

The mask substrate 2320 may have the same size or shape as the mother semiconductor substrate 3000 as a substrate of an ultra-high resolution display.

Multiple mask cells MSC may be arranged to correspond to multiple display cells DPC of the mother semiconductor substrate 3000. For example, in a deposition process for manufacturing the display device 10, multiple mask cells MSC may overlap multiple display cells DPC of the mother semiconductor substrate 3000, respectively.

At this time, to align multiple mask cells MSC to overlap multiple display cells DPC, the mother semiconductor substrate 3000 may include a first alignment mark AMK1, and the deposition mask 2000 may include a second alignment mark AMK2. The first alignment mark AMK1 and the second alignment mark AMK2 may each contain metal, but are not limited thereto.

Multiple mask cells MSC may be formed using semiconductor equipment or through a semiconductor process, but are not limited thereto. By forming multiple mask cells MSC on the mask substrate 2320 composed of a semiconductor wafer using semiconductor equipment or through a semiconductor process, the deposition mask 2000 according to the disclosure may be provided with an ultra-high resolution pattern. An ultra-high resolution display may be manufactured using this ultra-high resolution pattern.

The characteristics of the deposition mask 2000 described above may be substantially the same as the characteristics of the deposition masks 2000p and 2000q which will be described below.

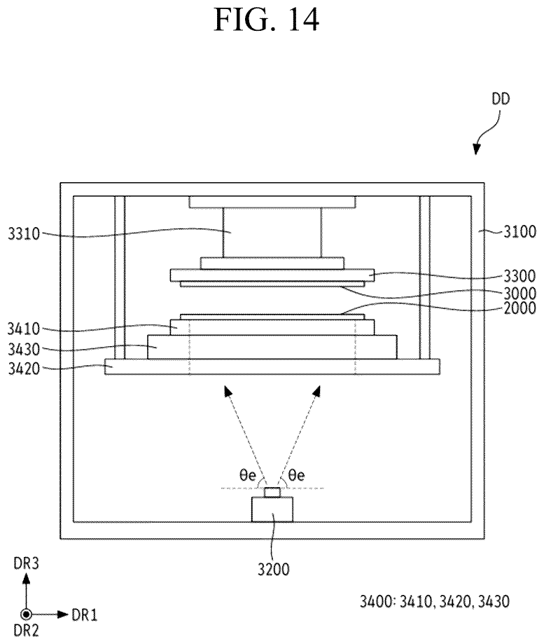

FIG. 14 is a schematic diagram for explaining a deposition device that manufactures a display panel by using a deposition mask according to an embodiment.

Referring to FIG. 14 in addition to FIGS. 1 to 13, a deposition device DD may be used to form light emitting material layers on the mother semiconductor substrate 3000 in a manufacturing process of the display panel 100. In another embodiment, the deposition device DD may be used to form the light emitting layer IL illustrated in FIG. 7.

The deposition device DD may include a process chamber 3100. The process chamber 3100 may have an internal space, and a deposition process for forming a deposition material layer on the mother semiconductor substrate 3000 may be performed in the internal space of the process chamber 3100. Although not illustrated, the process chamber 3100 may be connected to a vacuum pump (not illustrated), and the internal space of the process chamber 3100 may be created into a vacuum atmosphere by the vacuum chamber. An opening (not illustrated) for the entry and exit of the mother semiconductor substrate 3000 and the deposition mask 2000 may be provided on a side wall of the process chamber 3100, and may be opened and closed by a gate valve (not illustrated).

The deposition mask 2000 and the mother semiconductor substrate 3000 may be located to face each other. As an example, the deposition mask 2000 may be located to face a side of the third direction DR3, and the mother semiconductor substrate 3000 may be located to face another side of the third direction DR3. The mother semiconductor substrate 3000 may be supported by a substrate chuck 3300. For example, the substrate chuck 3300 may support the mother semiconductor substrate 3000 so that the front side of the mother semiconductor substrate 3000 faces downward, and may position the mother semiconductor substrate 3000 on the deposition mask 2000 to perform a deposition process.

An upper driving unit 3310 moving and rotating the substrate chuck 3300 may be disposed above the substrate chuck 3300 to adjust the position and angle of the mother semiconductor substrate 3000. For example, the upper driving unit 3310 may move the substrate chuck 3300 in the first and second directions DR1 and DR2 to adjust the horizontal position of the mother semiconductor substrate 3000, and may move the substrate chuck 3300 in the third direction DR3 to adjust the vertical position of the mother semiconductor substrate 3000. For example, the first direction DR1, the second direction DR2, and the third direction DR3 may be an X-axis direction, a Y-axis direction, and a Z-axis direction, respectively.

The deposition mask 2000 may be disposed on a mask stage 3400. The mask stage 3400 may include a mask chuck 3410 for supporting the deposition mask 2000, a support plate 3420, and a lower driving unit 3430.

The mask chuck 3410 may have a circular ring shape to support the edge portion of the deposition mask 2000. For example, the mask chuck 3410 may be an electrostatic chuck to hold the edge portion of the deposition mask 2000 using an electrostatic force.

The support plate 3420 may have an opening to allow the deposition mask 2000 to be exposed toward the deposition source 3200, and the lower driving unit 3430 for adjusting the position and angle of the lower deposition mask 2000 may be disposed between the support plate 3420 and the mask chuck 3410. As an example, the lower driving unit 3430 may move the mask chuck 3410 in the first and second directions DR1 and DR2 to adjust the horizontal position of the deposition mask 2000, and may rotate the mask chuck 3410 around the Z-axis to adjust the azimuthal angle of the deposition mask 2000.

The deposition source 3200 may be positioned on another side of the third direction DR3. The deposition source 3200 may be positioned below the deposition mask 2000. The deposition source 3200 may be sprayed in a range of a deposition incident angle θe, and the sprayed deposition material may be mounted on a mother semiconductor substrate 3000 through the deposition mask 2000. For example, the deposition angle θe may be about 60 degrees or more.

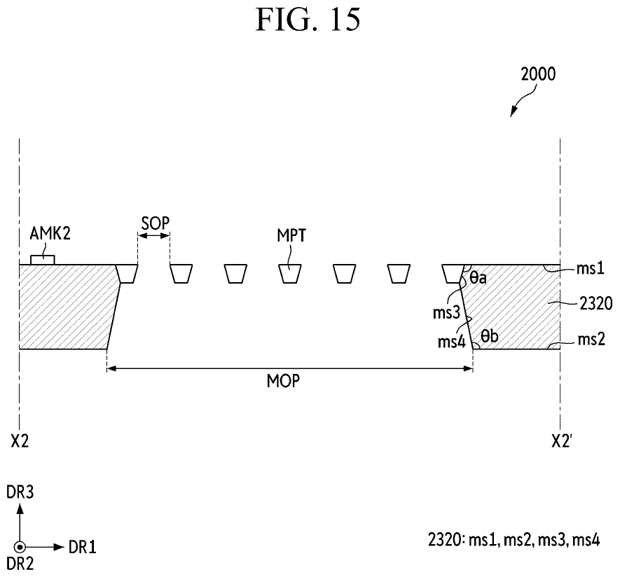

FIG. 15 is a schematic cross-sectional view taken along line X2-X2′ of FIG. 13.

Referring to FIG. 15 in addition to FIGS. 1 to 14, the deposition mask 2000 according to an embodiment may include a mask substrate 2320 and a mask pattern MPT.

The mask substrate 2320 may define a mask opening MOP, and the mask substrate 2320 may be positioned to surround the mask opening MOP. The mask opening MOP may be formed in plural numbers corresponding to the mask cells MSC of FIG. 13. For example, multiple mask openings MOP may be disposed in each of multiple mask cells MSC. However, the disclosure is not limited thereto, and the mask opening MOP may be formed as one throughout multiple mask cells MSC.

As described above, the mask substrate 2320 may be a silicon wafer.

The mask substrate 2320 may include a first surface ms1, a second surface ms2, a first side surface ms3, and a second side surface ms4. The first surface ms1 may be a surface facing a side of the third direction DR3, the second surface ms2 may be a surface facing the first surface ms1, and the first side surface ms3 and the second side surface ms4 may be surfaces facing the mask opening MOP. The side of the third direction DR3 described above may mean a direction perpendicular to the mask substrate 2320.

The first side surface ms3 of the mask substrate 2320 may connect the first surface ms1 and the second side surface ms4, the second side surface ms4 may be a surface connecting the second surface ms2 and the first side surface ms3, and the first surface ms1 and the second surface ms2 may be connected by the first side surface ms3 and the second side surface ms4.

The first side surface ms3 of the mask substrate 2320 may be an inclined surface. For example, an angle formed by the first surface ms1 and the first side surface ms3 of the mask substrate 2320 may be an obtuse angle, and for example, a first inclined angle θa may have a range of about 92 degrees or more and about 130 degrees or less.

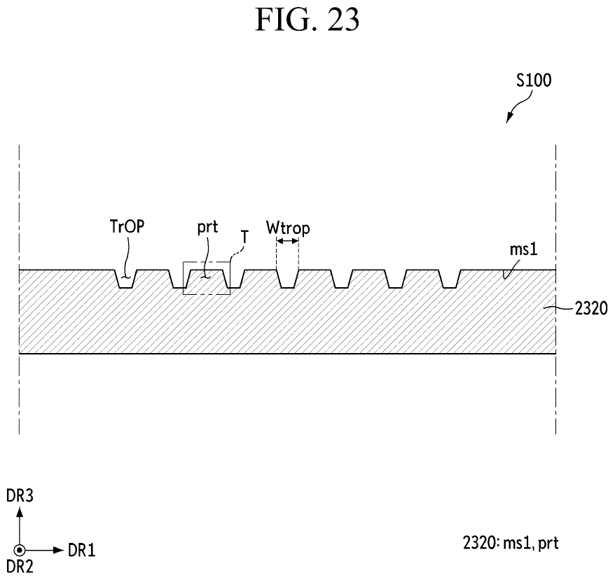

The first inclined angle θa of the mask substrate 2320 may be formed as the mask substrate 2320 is formed to include a protrusion prt (see FIG. 23) in a manufacturing process of the deposition mask 2000. Details will be described below.

The first side surface ms3 of the mask substrate 2320 may be positioned to be in contact with the mask pattern MPT. In another embodiment, the first side surface ms3 of the mask substrate 2320 may be covered by the mask pattern MPT.

A second inclined angle θb formed by the second surface ms2 and the second side surface ms4 of the mask substrate 2320 may be a right angle or an obtuse angle. For example, in case that the second inclined angle θb is an obtuse angle, the second side surface ms4 may be an inclined surface. The second side surface ms4 of the mask substrate 2320 may be formed as a portion of the mask substrate 2320 is removed by an etching process in the manufacturing process of the deposition mask 2000. The manufacturing process will be described below.

The second alignment mark AMK2 may be positioned on the mask substrate 2320. However, the disclosure is not limited thereto, and the position of the second alignment mark AMK2 may be modified.

Multiple mask patterns MPT may be positioned in a portion overlapping the mask opening MOP. Each of the mask patterns MPT may be spaced apart with a pixel opening SOP interposed therebetween.

The pixel opening SOP according to an embodiment may be in communication with the mask opening MOP. Accordingly, the mask opening MOP and the pixel opening SOP may provide a passage through which a deposition material for forming the pixel PX of the display panel 100 included in the display device 10 may move.

Multiple mask patterns MPT may be spaced apart from each other in the first direction DR1 or the second direction DR2 in cross section, but may be one pattern connected to each other in a plan view. In another embodiment, the mask pattern MPT may refer to all of multiple patterns as a configuration or may refer to each of multiple patterns. For example, multiple mask patterns MPT may be used interchangeably to refer to the entirety of a group of multiple patterns as one configuration or refer to each of multiple patterns.

The mask pattern MPT may include inorganic insulating material, and for example, include any one of silicon nitride and silicon oxide.

The mask pattern MPT may have a reverse-tapered shape or an inverted trapezoid shape. The characteristics of the mask pattern MPT described above may be common characteristics of mask patterns MPT1, MPT3, MPT5, and MPT7 which will be described later.

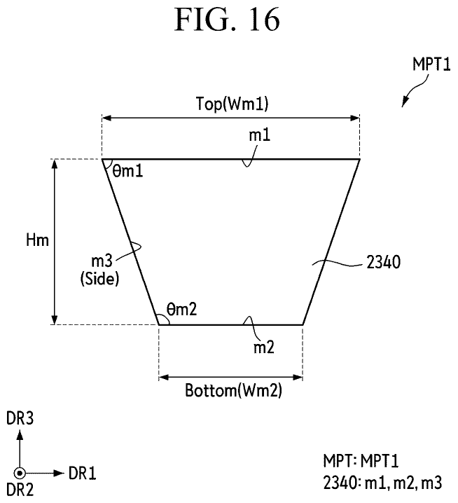

FIG. 16 is a schematic cross-sectional view of an enlarged mask pattern in FIG. 15.

Referring to FIG. 16 in addition to FIGS. 1 to 15, the mask pattern MPT1 may include a first coating layer 2340. The first coating layer 2340 may include an inorganic insulating material, and for example, may include at least any one of silicon nitride or silicon oxide.

The mask pattern MPT1 may be a single layer formed of one material.

The mask pattern MPT1 may have a reverse-tapered shape or an inverted trapezoid shape.

The first coating layer 2340 may include a first surface m1, a second surface m2, and a first side surface m3. The first surface m1 may be a surface facing a side of the third direction DR3, the second surface m2 may be a surface facing the first surface m1, and the first side surface m3 may be a surface connecting the first surface m1 and the second surface m2.

The first surface m1 of the first coating layer 2340 may be the top surface of the mask pattern MPT1, the second surface m2 thereof may be the bottom surface of the mask pattern MPT1, and the first side surface m3 thereof may be the side surface of the mask pattern MPT1.

The first surface m1 of the first coating layer 2340 may be positioned on the same line as the first surface ms1 of the mask substrate 2320. In another embodiment, the top surface of the mask pattern MPT1 may be positioned on the same line as the first surface ms1 of the mask substrate 2320. Being positioned on the same line may mean being aligned in the first direction DR1.

A width Wm2 of the second surface m2 of the first coating layer 2340 may be smaller than a width Wm1 of the first surface m1. In another embodiment, the width Wm1 of the top surface of the mask pattern MPT1 may be greater than the width Wm2 of the bottom surface thereof in the first direction DR1.

The width Wm1 of the first surface m1 included by the first coating layer 2340, for example, the width Wm1 of the top surface of the mask pattern MPT1, may have a value of about 10 μm or less.

The range of the width Wm1 of the top surface described above may be an essential element for realizing high resolution. In another embodiment, in case where the width Wm1 of the top surface of the mask pattern MPT1 exceeds about 10 μm, it may be difficult to manufacture a high-resolution display device with narrow spacing between elements.

A height Hm of the mask pattern MPT1 may be about 15 μm or less. The height Hm of the mask pattern MPT1 may be the same as the height Hm of the first coating layer 2340.

The range of the height Hm described above may be an essential element for realizing a high-resolution. In another embodiment, in case where the height Hm exceeds about 15 μm, there may be difficulties in applying a process that requires the material for forming the light emitting layer IL to be deposited between the narrow pixel openings SOP.

The side surface of the mask pattern MPT1, which is the first side surface m3 of the first coating layer 2340 may be an inclined surface. In another embodiment, a first inclined angle θm1 formed by the first surface m1 and the first side surface m3 of the first coating layer 2340 may be smaller than a second inclined angle θm2 formed by the second surface m2 and the first side surface m3. In another embodiment, the first inclined angle θm1 formed by the side surface and the top surface of the mask pattern MPT1 may be smaller than the second inclined angle θm2 formed by the side surface and the bottom surface.

The first inclined angle θm1 may be an acute angle and the second inclined angle θm2 may be an obtuse angle. For example, the first inclined angle θm1 may have a value of about 50 degrees to about 88 degrees, and the second inclined angle θm2 may have a value of about 92 degrees to about 130 degrees.

For example, in case where the mask pattern MPT1 of the deposition mask 2000 includes a value outside the range of the above-described first inclined angle θm1 and second inclined angle θm2, in case that the light emitting layer IL is formed on the mother semiconductor substrate 3000 as illustrated in FIG. 14, a portion of the light emitting material may not pass through the mask opening MOP and the pixel opening SOP and be deposited on the side surface and the bottom surface of the mask pattern MPT1. This may reduce the deposition efficiency of the light emitting layer IL and cause shadow defects in some areas where the light emitting efficiency of the light emitting layer IL decreases, which may lead to poor reliability of the display device 10. Accordingly, it may be significant that the mask pattern MPT1 includes the ranges of the above-described first inclined angle θm1 and the second inclined angle θm2.

The deposition mask 2000 according to an embodiment may include the mask pattern MPT1 of a reverse-tapered shape or an inverted trapezoid shape that includes the above-described range, thereby increasing deposition efficiency in the process of forming the display device 10, solving the shadow defect of the display device 10, and providing a high-resolution display device 10.

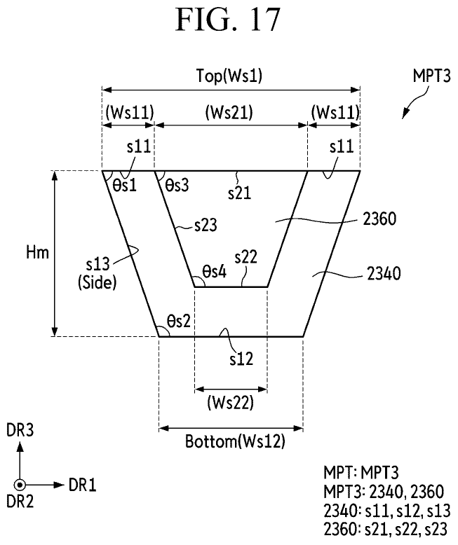

FIG. 17 is a schematic cross-sectional view of an enlarged mask pattern in FIG. 15 according to another embodiment.

Referring to FIG. 17 in addition to FIGS. 1 to 16, the mask pattern MPT3 may have a different shape from the mask pattern MPT1 by including a first coating layer 2340 and a second coating layer 2360.

Hereinafter, the same components as those of the above-described embodiment of the mask pattern MPT1 will be denoted by the same reference numerals, and an overlapping description therefor will be omitted or simplified and contents different from those described above will be mainly described.

The mask pattern MPT3 may have a reverse-tapered shape or an inverted trapezoid shape. Details will be described below.

The mask pattern MPT3 may include a first coating layer 2340 and a second coating layer 2360. The first coating layer 2340 and the second coating layer 2360 may include different materials. Details will be described below.

The first coating layer 2340 of the mask pattern MPT3 may include an inorganic material, and for example, may include silicon oxide (SiOₓ) having compressive stress properties.

The first coating layer 2340 may be formed through a CVD process during the manufacturing process, and may be formed with a uniform thickness Ws11 in a process error of less than about 10%.

The first coating layer 2340 may include a first surface s11, a second surface s12, and a first side surface s13. The first surface s11 may be a surface facing a side of the third direction DR3, the second surface s12 may be a surface facing the first surface s11, and the first side surface s13 may be a surface facing the outer side of the mask pattern MPT3 and connecting the first surface s11 and the second surface s12.

The first surface s11 of the first coating layer 2340 may be on the same line as the first surface ms1 of the mask substrate 2320 (see FIG. 15).

The second surface s12 of the first coating layer 2340 may be the bottom surface of the mask pattern MPT3, and the first side surface s13 thereof may be the side surface of the mask pattern MPT3. Accordingly, a width Ws12 of the second surface s12 may be the same as a width Ws12 of the bottom surface of the mask pattern MPT3.

The side surface of the mask pattern MPT3, which is the first side surface s13 of the first coating layer 2340 may be an inclined surface. In another embodiment, a first inclined angle θs1 formed by the first surface s11 and the first side surface s13 of the first coating layer 2340 may be smaller than a second inclined angle θs2 formed by the second surface s12 and the first side surface s13. In another embodiment, the first inclined angle θs1 formed by the side surface and the top surface of the mask pattern MPT3 may be smaller than the second inclined angle θs2 formed by the side surface and the bottom surface.

The first inclined angle θs1 may be an acute angle and the second inclined angle θs2 may be an obtuse angle. For example, the first inclined angle θs1 may have a value of about 50 degrees to about 88 degrees, and the second inclined angle θs2 may have a value of about 92 degrees to about 130 degrees.

The mask pattern MPT3 may include the above-described ranges of the first inclined angle θs1 and the second inclined angle θs2, thereby increasing deposition efficiency in the process of forming the display device 10 and solving shadow defects of the display device 10. Redundant descriptions will be omitted.

The second coating layer 2360 included in the mask pattern MPT3 may be positioned on the first coating layer 2340. The second coating layer 2360 may be surrounded by the first coating layer 2340.

The second coating layer 2360 may include an inorganic material, and for example, may include silicon nitride (SiNₓ) having tensile stress properties.

The mask pattern MPT3 may include the second coating layer 2360 with tensile stress properties and the first coating layer 2340 with compressive stress properties, thereby solving the reliability problem of the mask pattern MPT3. In another embodiment, the mask pattern MPT3 may include the first coating layer 2340 and the second coating layer 2360 with opposing stress properties, thereby solving the reliability problem that may be caused due to defect of membrane removal.

The second coating layer 2360 included in the mask pattern MPT3 may include a first surface s21, a second surface s22, and a first side surface s23. The first surface s21 may be a surface facing a side of the third direction DR3, the second surface s22 may be a surface facing the first surface s21, and the first side surface s23 may be a surface positioned to face the first coating layer 2340 and connecting the first surface s21 and the second surface s22.

The first surface s21 of the second coating layer 2360 may be located on the same line as the first surface s11 of the first coating layer 2340 and the first surface ms1 of the mask substrate 2320 (see FIG. 15).

The first side surface s23 may be an inclined surface. For example, a first inclined angle θs3 formed by the first surface s21 and the first side surface s23 may be smaller than a second inclined angle θs4 formed by the second surface s22 and the first side surface s23. The first inclined angle θs3 may be an acute angle, and the second inclined angle θs4 may be an obtuse angle.

A width Ws21 of the first surface s21 of the second coating layer 2360 may be greater than a width Ws22 of the second surface s22. In another embodiment, the second coating layer 2360 may have a reverse-tapered shape or an inverted trapezoid shape.

The top surface of the mask pattern MPT3 may mean a portion obtained by adding the first surface s11 of the first coating layer 2340 and the first surface s21 of the second coating layer 2360. In another embodiment, a width Ws1 of the top surface may be a value obtained by adding the width Ws11 of the first surface s11 of the first coating layer 2340 and the width Ws21 of the first surface s21 of the second coating layer 2360.

The top surface of the mask pattern MPT3 may be positioned on the same line as the first surface ms1 of the mask substrate 2320. Redundant descriptions will be omitted.

The width Ws1 of the top surface of the mask pattern MPT3 may be greater than the width Ws12 of the bottom surface of thereof. For example, the width Ws1 of the top surface of the mask pattern MPT3 may have a value of about 10 μm or less. The above-described range of the width Ws1 of the top surface may be an essential element for realizing high-resolution. Redundant descriptions will be omitted.

The height Hm of the mask pattern MPT3 may be about 15 μm or less. The height Hm of the mask pattern MPT3 may be the same as the height Hm of the first coating layer 2340. The above-described range height Hm of the mask pattern MPT3 above may be an essential element for realizing high-resolution. Redundant descriptions will be omitted.

The deposition mask 2000 according to an embodiment may include the mask pattern MPT3 of a reverse-tapered shape that includes the above-described range, thereby increasing deposition efficiency in the process of forming the display device 10, solving the shadow defect of the display device 10, and providing a high-resolution display device 10.

The mask pattern MPT3 included in deposition mask 2000 according to an embodiment may include the first coating layer 2340 and the second coating layer 2360 with opposing stress properties, thereby solving the reliability problem that may be caused due to defect of membrane removal.

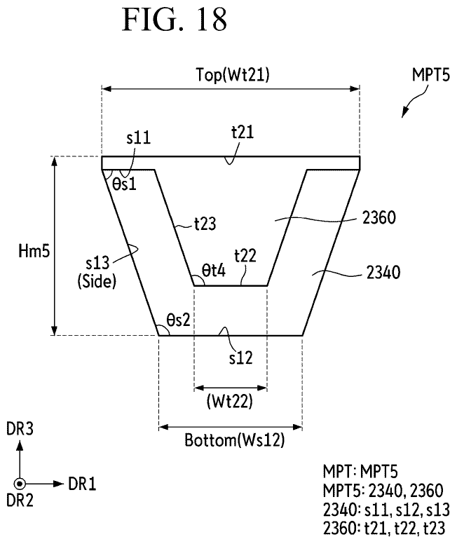

FIG. 18 is a schematic cross-sectional view of an enlarged mask pattern in FIG. 15 according to still another embodiment.

Referring to FIG. 18 in addition to FIGS. 1 to 17, a second coating layer 2360 of a mask pattern MPT5 may have a different shape from the second coating layer 2360 included in the mask pattern MPT3.

Hereinafter, the same components as those of the above-described embodiment of the mask pattern MPT3 will be denoted by the same reference numerals, and an overlapping description therefor will be omitted or simplified and contents different from those described above will be mainly described.

The mask pattern MPT5 may have a reverse-tapered shape or an inverted trapezoid shape. Details will be described below.

The mask pattern MPT5 may include a first coating layer 2340 and a second coating layer 2360. The first coating layer 2340 and the second coating layer 2360 of the mask pattern MPT5 may have the same material characteristics as the first coating layer 2340 and the second coating layer 2360 of the mask pattern MPT3. Accordingly, the mask pattern MPT5 according to an embodiment may include the second coating layer 2360 with tensile stress properties and the first coating layer 2340 with compressive stress properties, thereby solving reliability defects of the mask pattern MPT5. Redundant descriptions will be omitted.

The first coating layer 2340 of the mask pattern MPT5 may have the same structural characteristics as the first coating layer 2340 of the mask pattern MPT3. For example, the first coating layer 2340 of the mask pattern MPT5 may include a first surface s11, a second surface s12, and a first side surface s13, and the second surface s12 of the first coating layer 2340 may be the bottom surface of the mask pattern MPT5, and the first side surface s13 may be the side surface of the mask pattern MPT5.

A first inclined angle θs1 formed by the side surface and the first surface s11 of the mask pattern MPT5 may be smaller than a second inclined angle θs2 formed by the side surface and the bottom surface. For example, the first inclined angle θs1 may have a value of about 50 degrees to about 88 degrees, and the second inclined angle θs2 may have a value of about 92 degrees to about 130 degrees.

The mask pattern MPT5 may include the above-described ranges of the first inclined angle θs1 and the second inclined angle θs2, thereby increasing deposition efficiency in the process of forming the display device 10 and solving shadow defects of the display device 10. Redundant descriptions will be omitted.

The second coating layer 2360 included in the mask pattern MPT5 may be positioned on the first coating layer 2340. The second coating layer 2360 may be in contact with and cover the first surface s11 of the first coating layer 2340.

The second coating layer 2360 included in the mask pattern MPT5 may include a first surface t21, a second surface t22, and a first side surface t23. The first surface t21 may be a surface facing a side of the third direction DR3, the second surface t22 may be a surface facing the first surface t21, and the first side surface t23 may be a surface facing the side surface of the mask pattern MPT5.

A width Wt21 of the first surface t21 of the second coating layer 2360 may be greater than a width Wt22 of the second surface t22 thereof in the first direction DR1. The first side surface t23 of the second coating layer 2360 may be an inclined surface. For example, an inclined angle θt4 formed by the second surface t22 and the first side surface t23 of the second coating layer 2360 may be an obtuse angle.

The first surface t21 of the second coating layer 2360 may be the top surface of the mask pattern MPT5. In another embodiment, the width Wt21 of the top surface of the mask pattern MPT5 may be the same as the width Wt21 of the first surface t21 of the second coating layer 2360.

The top surface of the mask pattern MPT5 may be positioned on the same line as the first surface ms1 of the mask substrate 2320. Redundant descriptions will be omitted.

The width Wt21 of the top surface of the mask pattern MPT5 may have a value of about 10 μm or less. The above-described range of the width Wt21 of the top surface may be an essential element for realizing high-resolution. Redundant descriptions will be omitted.

A height Hm5 of the mask pattern MPT5 may be about 15 μm or less. The height Hm5 of the mask pattern MPT5 may be the same as the sum of the height of the first coating layer 2340 and the second coating layer 2360. The above-described range of the mask pattern MPT5 may be an essential element for realizing high-resolution. Redundant descriptions will be omitted.

The deposition mask 2000 according to an embodiment may include the mask pattern MPT5 of a reverse-tapered shape that includes the above-described range, thereby increasing deposition efficiency in the process of forming the display device 10, solving the shadow defect of the display device 10, and providing a high-resolution display device 10.

The mask pattern MPT5 included in the deposition mask 2000 according to an embodiment may include the first coating layer 2340 and the second coating layer 2360 with opposing stress properties, thereby solving the reliability problem that may be caused due to defect of membrane removal.

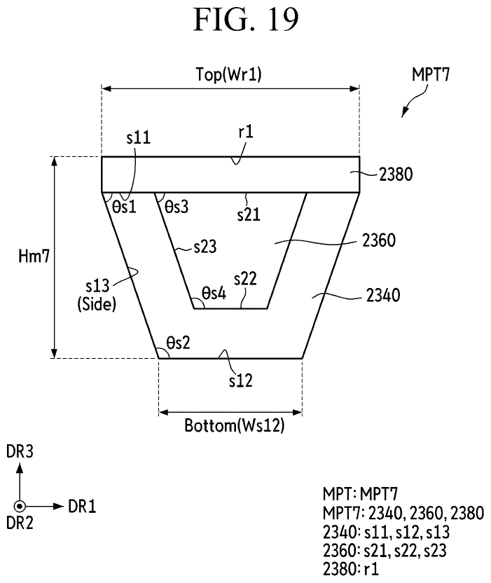

FIG. 19 is a schematic cross-sectional view of an enlarged mask pattern in FIG. 15 according to still another embodiment.

Referring to FIG. 19, a mask pattern MPT7 may include a metal coating layer 2380 and have a different shape from the mask pattern MPT3.

Hereinafter, the same components as those of the above-described embodiment of the mask pattern MPT3 will be denoted by the same reference numerals, and an overlapping description therefor will be omitted or simplified and contents different from those described above will be mainly described.

The mask pattern MPT7 may have a reverse-tapered shape or an inverted trapezoid shape. Details will be described below.

The mask pattern MPT7 may include a first coating layer 2340, a second coating layer 2360, and a metal coating layer 2380. The first coating layer 2340 and the second coating layer 2360 of the mask pattern MPT7 may have the same material characteristics and structural characteristics as the first coating layer 2340 and the second coating layer 2360 of the mask pattern MPT3.

For example, the mask pattern MPT7 may include the second coating layer 2360 with tensile stress properties and the first coating layer 2340 with compressive stress properties, thereby solving the reliability problem of the mask pattern MPT7.

Moreover, the mask pattern MPT7 may include a first surface s11, a second surface s12, and a first side surface s13, and the second surface s12 of the first coating layer 2340 may be the bottom surface of the mask pattern MPT7, and the first side surface s13 of the first coating layer 2340 may be the side surface of the mask pattern MPT7. A first inclined angle θs1 formed by the first surface s11 and the first side surface s13 of the first coating layer 2340 may be smaller than a second inclined angle θs2 formed by the second surface s12 and the first side surface s13, and for example, the first inclined angle θs1 may have a value of about 50 degrees to about 88 degrees, and the second inclined angle θs2 may have a value of about 92 degrees to about 130 degrees.

The second coating layer 2360 of the mask pattern MPT7 may include a first surface s21, a second surface s22, and a first side surface s23, and a first inclined angle θs3 formed by the first surface s21 and the first side surface s23 may be smaller than a second inclined angle θs4 formed by the second surface s22 and the first side surface s23. The first inclined angle θs3 may be an acute angle, and the second inclined angle θs4 may be an obtuse angle.

The mask pattern MPT7 may include the above-described ranges of the first inclined angle θs1 and the second inclined angle θs2, thereby increasing deposition efficiency in the process of forming the display device 10 and solving shadow defects of the display device 10. Redundant descriptions will be omitted.

The metal coating layer 2380 may be positioned on the first coating layer 2340 and the second coating layer 2360. The metal coating layer 2380 may be in contact with the first coating layer 2340 and the second coating layer 2360. The metal coating layer 2380 may cover the first surface s11 of the first coating layer 2340 and the first surface s21 of the second coating layer 2360.

The metal coating layer 2380 may include metal, and for example, may include any one of copper (Cu), aluminum (Al), tungsten (W), molybdenum (Mo), chromium (Cr), gold (Au), titanium (Ti), nickel (Ni), and neodymium (Nd).

The metal coating layer 2380 may secure the rigidity of the mask pattern MPT7. For example, the metal coating layer 2380 may solve problems such as sagging of the mask pattern MPT7 caused by gravity during the manufacturing process and damage caused by external forces and static electricity that occur during the process.

The metal coating layer 2380 may include a first surface r1. The first surface r1 may be a surface facing the side of the third direction DR3. The first surface r1 of the metal coating layer 2380 may be the top surface of the mask pattern MPT7. For example, a width of the first surface r1 of the metal coating layer 2380 may be the same as a width Wr1 of the top surface of the mask pattern MPT7. For example, the width Wr1 of the top surface of the mask pattern MPT7 may have a value of about 10 μm or less. The above-described range of the width Wr1 of the top surface may be an essential element for realizing high-resolution. Redundant descriptions will be omitted.

The top surface of the mask pattern MPT7 may be positioned on the same line as the first surface ms1 of the mask substrate 2320. Redundant descriptions will be omitted.

Because the metal coating layer 2380 may be formed with a uniform thickness in about 10% process error, the surface opposite the first surface r1 also has the same value as the width Wr1 of the top surface of the mask pattern MPT7, and according to an embodiment, the surface facing the first surface r1 may be explained as the top surface of the mask pattern MPT7.

A height Hm7 of the mask pattern MPT7 may be about 15 μm or less. The height Hm7 of the mask pattern MPT7 may be the same as the value of sum of the heights of the first coating layer 2340 and the metal coating layer 2380. The above-described range of the height Hm7 of the mask pattern MPT7 may be an essential element for realizing high-resolution. Redundant descriptions will be omitted.

The deposition mask 2000 according to an embodiment may include the mask pattern MPT7 of a reverse-tapered shape that includes the above-described range, thereby increasing deposition efficiency in the process of forming the display device 10, solving the shadow defect of the display device 10, and providing a high-resolution display device 10.

The mask pattern MPT7 included in the deposition mask 2000 according to an embodiment may include the first coating layer 2340 and the second coating layer 2360 with opposing stress properties, thereby solving the reliability problem that may be caused due to defect of membrane removal.

In addition, since the mask pattern MPT7 included in the deposition mask 2000 according to an embodiment includes the metal coating layer 2380, the mechanical strength reliability of the mask pattern MPT7 may be improved.

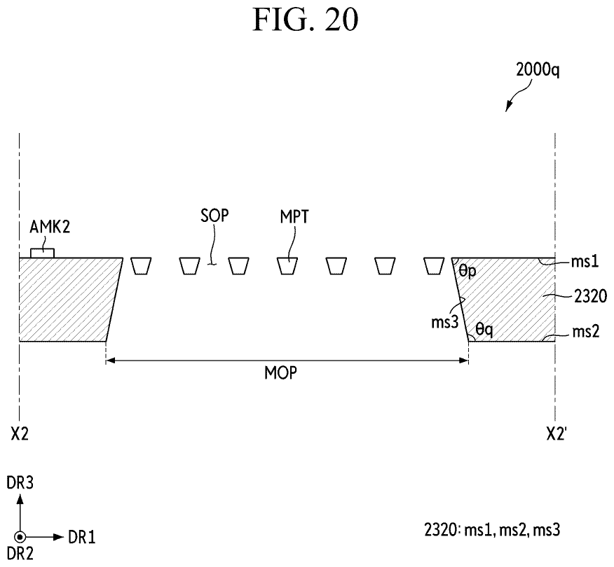

FIG. 20 is a schematic cross-sectional view taken along line X2-X2′ of FIG. 13 according to another embodiment.

Referring to FIG. 20 in addition to FIG. 1 to 19, a deposition mask 2000q may include a mask substrate 2320 and a mask pattern MPT.

The mask substrate 2320 may define a mask opening MOP, and the mask substrate 2320 may be positioned to surround the mask opening MOP. As described above, the mask substrate 2320 may be a silicon wafer.

The mask substrate 2320 may include a first surface ms1, a second surface ms2, and a first side surface ms3. The first surface ms1 may be a surface facing a side of the third direction DR3, the second surface ms2 may be a surface facing the first surface ms1, and the first side surface ms3 may be a surface facing the mask opening MOP. The first side surface ms3 of the mask substrate 2320 may connect the first surface ms1 and the second surface ms2.

The first side surface ms3 of the mask substrate 2320 may be an inclined surface. For example, an inclined angle θp formed by the first surface ms1 and the first side surface ms3 of the mask substrate 2320 may be an acute angle, and for example, the inclined angle θp may have a value of about 50 degrees to about 88 degrees.

The reason that the inclined angle θp of the mask substrate 2320 has the range described above may be caused as a mask pattern MPT is formed after forming the mask substrate 2320 to include a protrusion prt (see FIG. 23) during the manufacturing process of the deposition mask 2000q.

The first side surface ms3 of the mask substrate 2320 may be spaced apart from the mask pattern MPT with a pixel opening SOP interposed therebetween.

The second alignment mark AMK2 may be positioned on the mask substrate 2320. However, the disclosure is not limited thereto, and the position of the second alignment mark AMK2 may be modified.

Multiple mask patterns MPT may be positioned in a portion overlapping the mask opening MOP. Each of the mask patterns MPT may be spaced apart from each other with the pixel opening SOP interposed therebetween.

The mask pattern MPT included in the deposition mask 2000q may include the entire shapes of the mask patterns MPT1, MPT3, MPT5, and MPT7 described above. Redundant descriptions will be omitted.

Hereinafter, a manufacturing method of the deposition mask 2000 of FIG. 15 will be described.

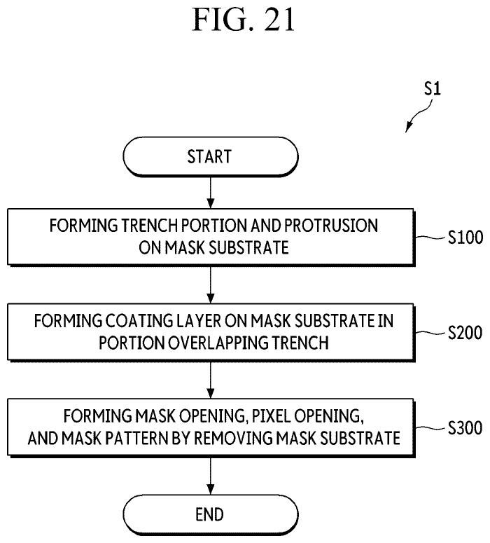

FIG. 21 is a schematic flowchart showing a method of manufacturing a deposition mask according to an embodiment.

Referring to FIG. 21, a manufacturing method S1 of a deposition mask according to an embodiment may include forming a trench portion and a protrusion on a mask substrate (S100), forming a coating layer on the mask substrate in a portion overlapping the trench (S200), and forming a mask opening, a pixel opening, and a mask pattern by removing the mask substrate (S300).

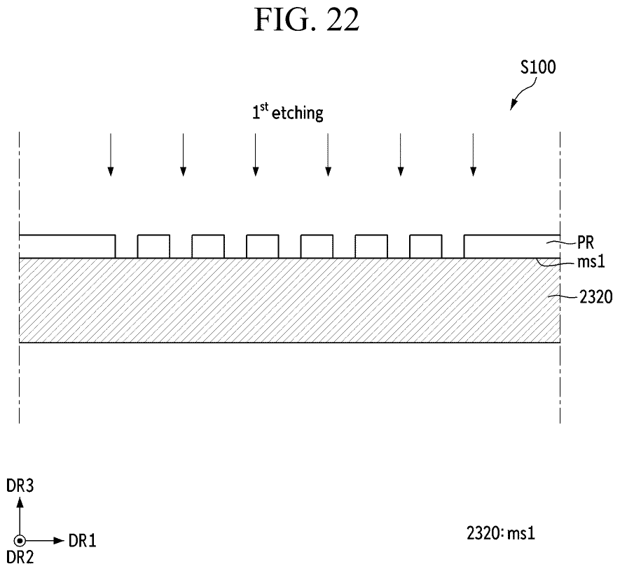

FIGS. 22 and 23 are schematic cross-sectional views of step (S100) of FIG. 21.

Firstly, the step (S100) of forming a trench portion and a protrusion on a mask substrate is described.

Referring to FIGS. 22 and 23, multiple photoresists PR are formed on a mask substrate 2320. As described above, the mask substrate 2320 may be a semiconductor wafer. Redundant descriptions will be omitted.

In the process, multiple photoresists PR may be disposed to be spaced apart. Thereafter, a first etching (1^{st} etching) may be performed using multiple photoresists PR as a mask. For example, the first etching (1^{st} etching) may be performed as any one of a wet-etching process or a dry-etching process and may be performed in a first surface ms1 direction of the mask substrate 2320.

For example, in case that a dry-etching process is performed as the first etching (1^{st} etching), a reactive ion etching (RIE) process using a reaction gas such as CHF₃, CH₃F, CH₂F₂, CHF₆, CF₄, C₂F₆, or C₃F₆, and a sputtering gas such as Ar or O₂/Ar may be performed. For example, an inductively coupled plasma (ICP) source or a capacitively coupled plasma (CCP) source may be used as a plasma source.

For example, in case that a wet-etching process is performed as the first etching (1^{st} etching), the first etching (1^{st} etching) may be performed using an etchant including tetramethyl ammonium hydroxide (TMAH) or potassium hydroxide (KOH).

In the process, a portion of the mask substrate 2320 not overlapping multiple photoresists PR may be removed, and accordingly, the first surface ms1 of the mask substrate 2320 may have an uneven shape in which protrusions and indentations are continuously repeated in the third direction DR3 (or thickness direction). In another embodiment, the mask substrate 2320 may have a protrusion prt of a normal-tapered shape or a trapezoid shape. The protrusion prt maybe formed in plural numbers, and multiple protrusions prt may be spaced apart from each other with a trench portion TrOP therebetween. The trench portion TrOP may refer to a relatively depressed portion due to etching of the mask substrate 2320, and the protrusion prt may refer to a relatively protruding portion due to the remaining mask substrate 2320.

A width Wtrop of the trench portion TrOP in the first direction DR1 may have a value of about 10 μm or less. The width Wtrop of the trench portion TrOP may be a major factor in adjusting the width of the upper surface of a mask pattern MPT when forming the mask pattern MPT in a subsequent process.

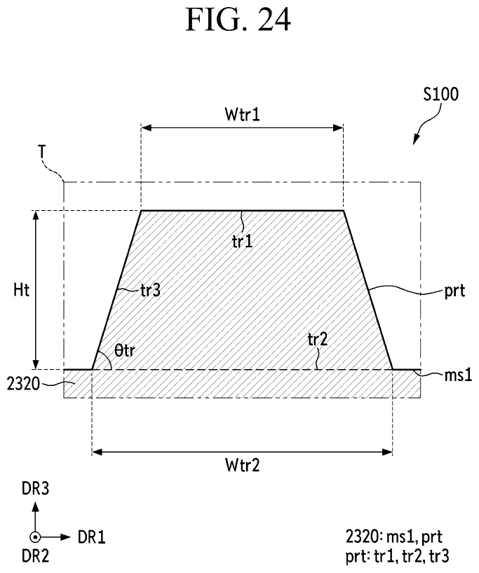

FIG. 24 is a schematic cross-sectional view of an enlarged area T in FIG. 23.

Referring to FIG. 24 in addition to FIGS. 22 and 23, the protrusion prt may have a normal-tapered shape or a trapezoid shape in the process.

For example, the protrusion prt may include a first surface tr1, a second surface tr2, and a first side surface tr3. The first surface tr1 may be a surface facing a side of the third direction DR3, the second surface tr2 may be an imaginary surface facing the first surface tr1, and the first side surface tr3 may be a surface connecting the first surface tr1 and the second surface tr2.

In the process, an inclined angle θtr formed by the second surface tr2 and the first side surface tr3 of the protrusion prt may have a value of about 50 degrees to about 88 degrees. Moreover, in the process, a with Wtr2 of the second surface tr2 may be greater than a width Wtr1 of the first surface tr1.

The range of the inclined angle θtr of the protrusion prt described above may be a major factor in adjusting a taper angle range of the mask pattern MPT when forming the mask pattern MPT in a subsequent process.

In the process, a height Ht of the protrusion prt may have a value of about 15 μm or less. The height Ht of the protrusion prt described above may be a major factor in adjusting the height of the mask pattern MPT when forming the mask pattern MPT in a subsequent process.

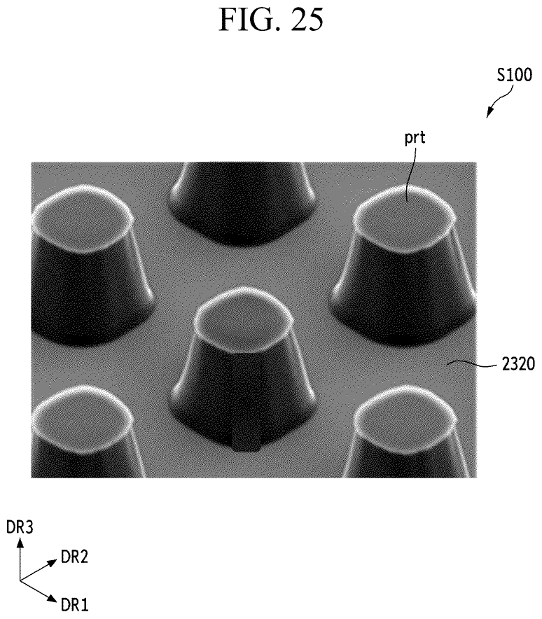

FIG. 25 is a schematic perspective view of an enlarged mask substrate including a protrusion in FIG. 24.

Referring to FIG. 25, in a perspective view, the protrusion prt of the mask substrate 2320 may have the shape shown in the drawing. For example, in a perspective view, the area of the cross-section of the protrusion prt of the mask substrate 2320 cut in the first direction DR1 and the second direction DR2 may reduce toward the third direction DR3.

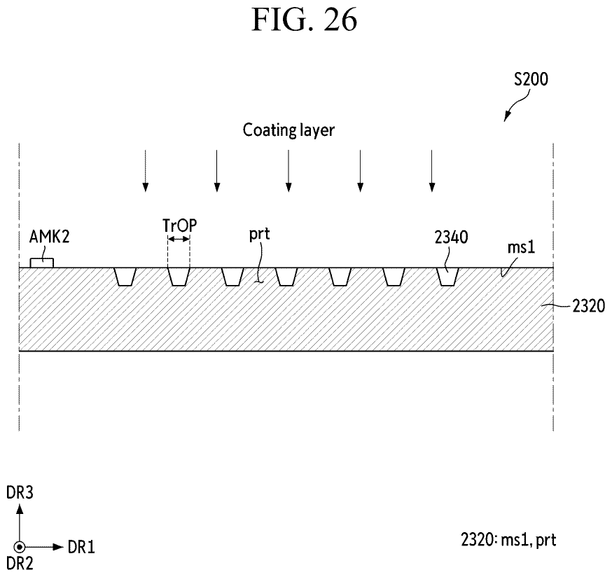

FIG. 26 is a schematic cross-sectional view of step (S200) of FIG. 21.

Secondly, the step (S200) of forming a coating layer on the mask substrate in a portion overlapping a trench portion is described.

Referring to FIG. 26 in addition to FIGS. 1 to 25, a coating layer may be formed on the mask substrate 2320 in a portion overlapping the trench portion TrOP. In the process, the coating layer may be formed (or only formed) in a portion overlapping the trench portion TrOP using a fine metal mask. However, the disclosure in not limited thereto, and the coating layer according to an embodiment may be located on a portion of the mask substrate 2320 in a portion not overlapping the trench portion TrOP.

In the process, the coating layer may be formed by a thermal oxidation or chemical vapor deposition process.

For example, in case that the coating layer is formed by a thermal oxidation, the first surface ms1 of the mask substrate 2320 may be oxidized in an atmosphere containing at least one of water vapor, oxygen, or high temperature, thereby forming the coating layer. The process may form a high-quality coating layer, and in the process, silicon is consumed to form the coating layer at a rate of about 55% above and about 45% below the first surface ms1 of the mask substrate 2320.

For example, in case that the coating layer is formed by a chemical vapor deposition process, a first source gas including silicon and a second source gas including any one of gas, nitrogen, or oxygen may be supplied to inside a chamber, and then, the coating layer may be formed by a reaction between the first source gas and the second source gas.

In the process, a first coating layer 2340 may be formed in a portion overlapping the trench portion TrOP. In the process, as the mask substrate 2320 has a normal-tapered shape or a trapezoid shape, the first coating layer 2340 may have a reverse-tapered shape or a trapezoid shape without a separate additional process. Since the first coating layer 2340 is already described with reference to FIGS. 15 to 19, Redundant descriptions will be omitted.

For convenience of description, a coating layer is illustrated and described as including the first coating layer 2340, but in case that the mask pattern MPT includes a second coating layer 2360 and a metal coating layer 2380 in addition to the first coating layer 2340, the second coating layer 2360 and the metal coating layer 2380 may be formed in the process.

For example, the second coating layer 2360 may be formed by a chemical vapor deposition process, and the metal coating layer 2380 may be formed by an E beam process.

Subsequently, a second alignment mark AMK2 is formed on the first coating layer 2340. For example, the second alignment mark AMK2 may be formed by patterning an alignment mark material layer through a photolithography process. The alignment mark material layer may include metal, but the disclosure is not limited thereto.

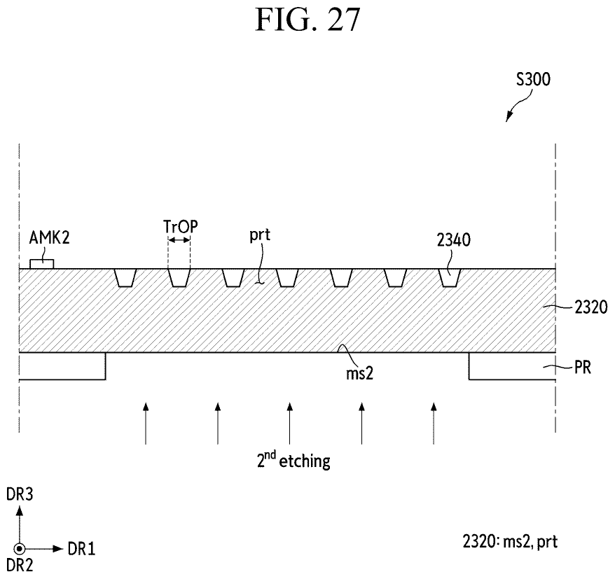

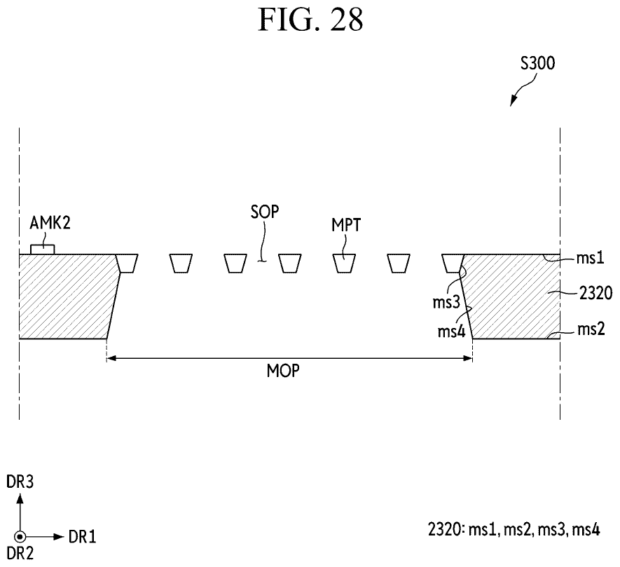

FIGS. 27 and 28 are schematic cross-sectional views of step (S300) of FIG. 21.

Hereinafter, the step (S300) of forming a mask opening, a pixel opening, and a mask pattern by removing a mask substrate will be described.

Referring to FIGS. 27 and 28, after forming the photoresist PR on the second surface ms2 of the mask substrate 2320, a second etching (2^{nd} etching) may be performed using the photoresist PR as a mask. For example, the second etching (2^{nd} etching) may be performed as at least any one of a dry-etching process or a wet-etching process.

In the process, the second etching (2^{nd} etching) may be performed in a second surface ms2 direction of the mask substrate 2320. In another embodiment, the second etching (2^{nd} etching) may be performed in the rear direction.

In the process, the mask substrate 2320 not overlapping the photoresist PR may be removed, and accordingly, a mask opening MOP, a pixel opening SOP, and a mask pattern MPT may be formed.

In the process, the mask opening MOP and the pixel opening SOP may be in communication, and the mask pattern MPT may be formed in a reverse-tapered shape as described above. In the process, the remaining mask substrate 2320 may include a first surface ms1, a second surface ms2, a first side surface ms3, and a second side surface ms4. Redundant descriptions will be omitted.

As a result, the deposition mask 2000 shown in FIG. 15 may be formed. The detailed structure of the mask pattern MPT has already been described and will be omitted.

Since the mask substrate 2320 includes a normal-tapered protrusion prt, the deposition mask 2000 may form a mask pattern MPT having a reverse-tapered shape even without a separate additional process. Accordingly, the deposition mask 2000 according to an embodiment may be easily manufactured.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A deposition mask comprising:
a mask substrate disposed to surround a mask opening and having a first surface; and
a plurality of mask patterns disposed to overlap the mask opening and spaced apart from each other with a pixel opening between the plurality of mask patterns,
wherein each mask pattern includes an upper surface facing a side of a perpendicular direction of the mask substrate and a lower surface facing the upper surface,
a width of an upper surface is greater than a width of the lower surface,
a width of the upper surface is about 10 μm or less, and
the first surface of the mask substrate and the upper surface of the mask pattern are disposed on a same line.

2. The deposition mask of claim 1, wherein
each of the plurality of the mask patterns further comprises a side surface facing the mask opening and connecting the upper surface and the lower surface, and
a first inclined angle formed by the upper surface and the side surface and a second inclined angle formed by the lower surface and the side surface are different.

3. The deposition mask of claim 2,
wherein the first inclined angle is an acute angle, and the second inclined angle is an obtuse angle.

4. The deposition mask of claim 3,
wherein the first inclined angle has a value of about 50 degrees to about 88 degrees.

5. The deposition mask of claim 4,
wherein the second inclined angle has a value of about 92 degrees to about 130 degrees.

6. The deposition mask of claim 1, wherein
each mask pattern has a reverse-tapered shape or an inverted trapezoid shape, and
a height of the mask pattern is about 15 μm or less.

7. The deposition mask of claim 1, wherein
the mask substrate comprises:
a second surface facing the first surface; and
a first side surface facing the mask opening and connected to the first surface.

8. The deposition mask of claim 7, wherein
the mask substrate further comprises a second side surface connected to the second surface,
the first surface and the second surface are connected to each other by the first side surface and the second side surface, and
an inclined angle formed by the first surface and the first side surface is an obtuse angle.

9. The deposition mask of claim 8,
wherein one of the plurality of the mask patterns is in contact with and covers the first side surface of the mask substrate.

10. The deposition mask of claim 7, wherein
the first side surface connects the first surface and the second surface,
an inclined angle formed by the first surface and the first side surface is an acute angle, and
one of the plurality of the mask patterns is spaced apart from the first side surface of the mask substrate with the pixel opening between the one of the plurality of mask patterns and the first side surface of the mask substrate.

11. The deposition mask of claim 1, wherein
each mask pattern comprises a first coating layer, and
the first coating layer comprises:
an upper surface disposed on a side of the perpendicular direction of the mask substrate;
a lower surface facing the upper surface; and
a first side surface connecting the upper surface and the lower surface, and
an inclined angle formed by the upper surface and the first side surface is about 50 degrees to about 88 degrees.

12. The deposition mask of claim 11, wherein
each mask pattern further comprises a second coating layer including a different material from the first coating layer,
the second coating layer has a reverse-tapered shape,
the first coating layer includes silicon oxide, and
the second coating layer includes silicon nitride.

13. The deposition mask of claim 12, wherein
the mask pattern further comprises a metal coating layer, and
the metal coating layer covers the first coating layer and the second coating layer.

14. A method of manufacturing a deposition mask, the method comprising:
forming a protrusion and a trench portion on a mask substrate;
forming a coating layer on the mask substrate in a portion overlapping the trench portion; and
forming a mask opening, a pixel opening, and a mask pattern by removing a mask substrate,
wherein, in cross-section, the protrusion has a normal-tapered shape or a trapezoid shape, and
a height of the protrusion is about 15 μm or less.

15. The method of claim 14, wherein
in the forming the protrusion and the trench portion on the mask substrate,
the protrusion comprises:
a first surface facing a side of a perpendicular direction of the mask substrate;
a second surface facing the first surface; and
a first side surface connecting the first surface and the second surface, and
a first inclined angle formed by the second surface and the first side surface is about 50 degrees to about 88 degrees.

16. The method of claim 15, wherein
in the forming of the protrusion and the trench portion on the mask substrate,
the protrusion is formed in plural, and the protrusions are spaced apart from with the trench portion between the protrusions.

17. The method of claim 16, wherein
in the forming of the protrusion and the trench portion on the mask substrate,
a width of the trench portion is about 10 μm or less.

18. The method of claim 17, wherein
the protrusion and the trench portion are formed as a portion of the mask substrate is removed by an etching process.

19. The method of claim 14, wherein
in the forming of the mask opening, the pixel opening, and the mask pattern by removing the mask substrate,
in cross-section, the mask pattern has a reverse-tapered shape.

20. A method of manufacturing a display panel, the method comprising:
placing a substrate on a deposition mask; and
forming light emitting material layers on the substrate by providing a gaseous light emitting material through the deposition mask,
wherein the deposition mask comprises:
a mask substrate disposed to surround a mask opening and having a first surface; and
a plurality of mask patterns disposed to overlap the mask opening and spaced apart from each other with a pixel opening between the plurality of mask patterns,
the mask pattern comprises an upper surface facing a side of a perpendicular direction of the mask substrate and a lower surface facing the upper surface,
a width of the upper surface is greater than a width of the lower surface,
a width of the upper surface is about 10 μm or less, and
the first surface of the mask substrate and the upper surface of the mask pattern are disposed on a same line, and the gaseous light emitting material is provided to the substrate through the mask opening and the pixel opening.
